(19) United States
(12) Patent Application Publication
(10) Pub. No.: US 2026/0190707 A1
(43) Pub. Date: Jul. 2, 2026

(54) LIGHT EMITTING DISPLAY APPARATUS

(71) Applicant: LG Display Co., Ltd., Seoul (KR)

(72) Inventor: Sungbin SHIM, Paju-si (KR)

(73) Assignee: LG Display Co., Ltd., Seoul (KR)

(21) Appl. No.: 19/386,791

(22) Filed: Nov. 12, 2025

(30) Foreign Application Priority Data
Dec. 30, 2024 (KR) 10-2024-0201453

(51) Int. Cl. H10K 59/131

(52) U.S. Cl. CPC H10K 59/131

(57) ABSTRACT

A light emitting display apparatus includes a substrate, a plurality of pixels, a pixel driving line provided along a first direction on the substrate, a gate line disposed on the substrate along a second direction crossing the first direction, an auxiliary line overlapping the pixel driving line, a pixel circuit connected to the pixel driving line, an overcoat layer covering the pixel circuit, a groove overlapping the auxiliary line, and a light emitting device layer disposed on the overcoat layer and connected to the pixel circuit.

### CROSS-REFERENCE TO RELATED APPLICATIONS

This application claims the benefit of and priority to Korean Patent Application No. 10-2024-0201453 filed on Dec. 30, 2024, the entire contents of which are incorporated herein by reference for all purposes as if fully set forth herein.

### BACKGROUND

### 1. Technical Field

The present disclosure relates to a light emitting display apparatus.

### 2. Description of Related Art

The light emitting display apparatus is a self-luminous display apparatus, and unlike the liquid crystal display apparatus, it does not require a separate light source, so it can be manufactured in a lightweight and thin manner. In addition, the light emitting display apparatus is not only advantageous in terms of power consumption by driving a low voltage, but also has excellent color arrangement, response speed, viewing angle, and contrast ratio, so it is in the spotlight as a next-generation display apparatus.

The light emitting display apparatus displays an image through light emission of a light emitting device layer including a light emitting device interposed between two electrodes. In this case, light generated according to light emission of the light emitting device is emitted to the outside through a substrate or the like.

Meanwhile, in the light emitting display apparatus, some of the light emitted from the light emitting device layer may not be emitted to the outside due to total reflection between a plurality of layers inside the display panel or at an interface. Accordingly, the light extraction efficiency of the light emitting display apparatus may be lowered.

The description of related art should not be considered prior art merely because it is mentioned in or associated with this section. The description of related art includes information that describes one or more aspects of the subject technology, and the description in this section does not limit the scope of the invention.

### SUMMARY

The inventor of this present disclosure has recognized the problems and needs of the related art, has performed extensive research and experiments, and has invented a light emitting display apparatus with a new structure that can improve light extraction efficiency.

One or more aspects of the present disclosure are directed to providing a light emitting display apparatus capable of improving light extraction efficiency of light emitted from a light emitting device layer.

One or more aspects of the present disclosure are directed to providing a light emitting display apparatus capable of being driven at low power by reducing overall power consumption as light extraction efficiency is improved.

Additional features, advantages, and aspects of the present disclosure are set forth in part in the present disclosure and will also be apparent from the present disclosure or may be learned by practice of the inventive concepts provided herein. Other features, advantages, and aspects of the present disclosure may be realized and attained by the descriptions provided in the present disclosure, or derivable therefrom, and claims hereof as well as the appended drawings.

To achieve these and other advantages and aspects of the present disclosure, as embodied and broadly described herein, in one or more aspects, a light emitting display apparatus comprises a substrate, a plurality of pixels, a pixel driving line provided along a first direction on the substrate, a gate line disposed on the substrate along a second direction crossing the first direction, an auxiliary line overlapping the pixel driving line, a pixel circuit connected to the pixel driving line, an overcoat layer covering the pixel circuit, a groove overlapping the auxiliary line, and a light emitting device layer disposed on the overcoat layer and connected to the pixel circuit.

Details of other example embodiments will be included in the detailed description of the disclosure and the accompanying drawings.

According to one or more embodiments of the present disclosure, since the light emitting display apparatus includes an auxiliary line overlapping the pixel driving line, a groove may be formed between each sub-pixel using an overcoat layer without adding a separate mask process. Accordingly, since a reflection direction of light toward adjacent sub-pixels may be controlled, light extraction efficiency of the light emitting display apparatus may be improved.

According to one or more embodiments of the present disclosure, since the light emitting display apparatus includes an auxiliary line and a groove overlapping the pixel driving line, light may be extracted even in a non-emission area. Accordingly, compared to a display apparatus without an auxiliary line and a groove, the light emitting efficiency may be improved to achieve the same or higher efficiency even at lower power, thereby reducing overall power consumption.

According to one or more embodiments of the present disclosure, since the light emitting display apparatus includes an auxiliary line and a groove overlapping the pixel driving line, both light dissipated by the wave guide and light completely reflected and dissipated inside the substrate may be emitted to the outside. Accordingly, light extraction efficiency can be maximized.

According to one or more embodiments of the present disclosure, since the light emitting display apparatus includes an auxiliary line and a groove overlapping the pixel driving line, color filters configured in adjacent sub-pixels may be spaced apart. Accordingly, light leakage and color mixing between sub-pixels may be prevented.

According to one or more embodiments of the present disclosure, since the light emitting display apparatus includes an auxiliary line overlapping the pixel driving line, a groove may be formed between each of the sub-pixels without adding a separate mask process (e.g., a halftone mask process, etc.). Accordingly, the light extraction efficiency of the light emitting display apparatus may be improved without adding to the complexity or cost of the manufacturing process.

According to one or more embodiments of the present disclosure, since the light emitting display apparatus includes an auxiliary line electrically connected to the pixel driving line, the resistance of the pixel driving line may be reduced.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a diagram schematically illustrating a light emitting display apparatus according to an embodiment of the present disclosure.

FIG. 2 is a diagram illustrating an arrangement structure of pixels according to an embodiment illustrated in FIG. 1.

FIG. 3 is a cross-sectional view taken along the line I-I′ shown in FIG. 2.

FIG. 4 is a cross-sectional view illustrating an example of an area A shown in FIG. 3.

FIG. 5 is a cross-sectional view illustrating an example of area B shown in FIG. 3.

FIG. 6 is a diagram illustrating an arrangement structure of pixels according to another embodiment illustrated in FIG. 1.

FIG. 7 is a cross-sectional view taken along the line II-II′ shown in FIG. 6.

FIG. 8 is a cross-sectional view illustrating an example of the area C shown in FIG. 7.

FIG. 9 is a cross-sectional view illustrating another example of the area C shown in FIG. 7.

FIG. 10 is a cross-sectional view illustrating another example of the area B shown in FIG. 2.

FIG. 11 is a cross-sectional view illustrating another example of the area B shown in FIG. 2.

FIGS. 12A to 12F illustrate a method of manufacturing a light emitting display apparatus according to an embodiment of the present disclosure.

FIGS. 13A to 13E illustrate a method of manufacturing a light emitting display apparatus according to an embodiment of the present disclosure.

Throughout the drawings and the detailed description, unless otherwise described, the same drawing reference numerals should be understood to refer to the same elements, features, and structures. The sizes, lengths, and thicknesses of layers, areas and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure. Further, the present disclosure is defined by the scope of claims and their equivalents.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, lines, circuits, components, electrodes, structures, transistors, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. In one or more examples, unless the context clearly indicates otherwise, an element may be one or more elements; and an element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, lines, circuits, components, electrodes, structures, transistors, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, lines, circuits, components, electrodes, structures, transistors, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

The expression that an element (e.g., layer, film, component, electrode, structure, transistor, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, the terms “first direction X,” “second direction Y,” “direction of an element,” and the like should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) one or more elements of the plurality of elements, (v) multiple elements of the plurality of elements, or (vi) all of the plurality of elements. Moreover, “at least some,” “some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, (iii) the element, or (iv) all portions of the element. Further, at least two or more elements can represent (i) two elements or (ii) more than two elements. In addition, one or more of a plurality of first items, a plurality of second items, and a plurality of third items can represent (i) a combination of items provided by two or more of the first item, the second item, and the third item or (ii) only one of the first item, the second item, or the third item.

The expression of a first element, a second elements “and/or” a third element should be understood as any one of the first, second and third elements or as any or all combinations of the first, second and third elements. Similar interpretations apply to the use of “and/or” with two elements or with more than three elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other, or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same or similar elements may be illustrated in other drawings, and like reference numerals may refer to like or similar elements unless stated otherwise. The same or similar elements may be denoted by the same reference numerals even if they are depicted in different drawings. Repetitive descriptions of the same or similar elements may be omitted for brevity, and the descriptions provided for elements in one or more figures may also apply to elements in other figures that use the same or similar reference numerals unless stated otherwise. In addition, for the convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

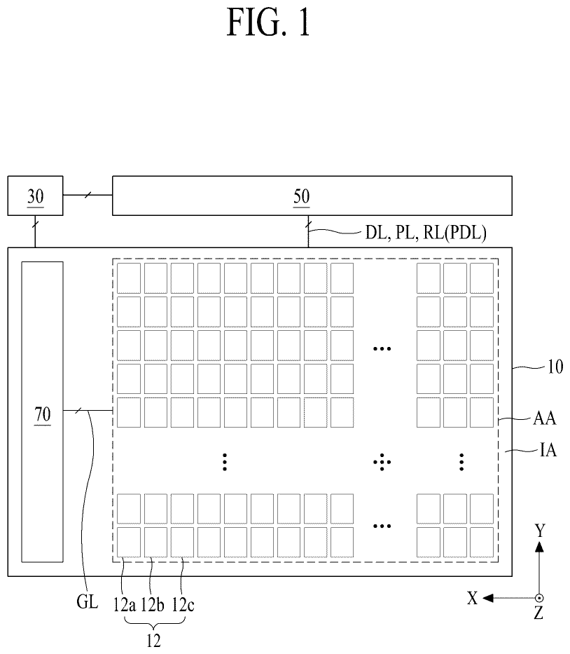

FIG. 1 is a diagram schematically illustrating a light emitting display apparatus according to an embodiment of the present disclosure.

Referring to FIG. 1, a light emitting display apparatus according to an embodiment of the present disclosure may include a display panel 10, a control circuit 30, a data driving circuit 50, and a gate driving circuit 70.

The display panel 10 may include a display area AA (or an active area) defined on a substrate, and a non-display area IA (or an inactive area) surrounding the display area AA.

The display area AA (or active area) defined on the substrate may include a plurality of pixels 12. A plurality of pixels 12 may be determined by a pixel driving line PDL and a gate line GL. The pixel driving line PDL may include a plurality of pixel power lines PL, a plurality of data lines DL, and a plurality of reference power lines RL.

The plurality of pixels 12 may include a plurality of sub-pixels 12a, 12b, and 12c disposed in an area defined by n gate lines GL and m data lines DL. Each of the n gate lines GL may extend along the first direction X and may be spaced apart from each other along the second direction Y crossing the first direction X. Each of the m data lines DL may extend along the second direction Y and may be spaced apart from each other along the first direction X.

A plurality of pixel power lines PL and a plurality of reference power lines RL may be disposed to be parallel to the data line DL. Each of the n gate lines GL may include an intersection portion crossing each of the m data lines DL, the plurality of pixel power lines PL, and the plurality of reference power lines RL. The intersection portion of each of the n gate lines GL may include at least one slit or opening portion for minimizing an overlapping area with other lines.

Each of the plurality of sub-pixels 12a, 12b, and 12c may display a color image corresponding to a gate signal supplied from the adjacent gate line GL and a data voltage supplied from the adjacent data line DL. For example, each of the plurality of sub-pixels 12a, 12b, and 12c may be arranged adjacent to each other in the longitudinal direction X of the gate line GL.

According to an embodiment of the present disclosure, each of the plurality of sub-pixels 12a, 12b, and 12c may include a pixel circuit disposed in a circuit area (or a non-light emitting portion) of the sub-pixel area, and a light emitting device layer disposed in an opening area (or a light emitting portion) of the sub-pixel area and electrically connected to the pixel circuit. For example, the pixel circuit may include at least two transistors and at least one capacitor. The light emitting device layer may include a self-emission device that displays an image by emitting light by a data signal provided from the pixel circuit.

Each of the plurality of sub-pixels 12a, 12b, and 12c may be defined as an area of a minimum unit in which actual light is emitted. For example, at least three pixels adjacent to each other may configure one pixel (or unit pixel) 12 for color display of an image.

One pixel 12 according to an embodiment may include first to third sub-pixels 12a, 12b, and 12c arranged adjacent to each other along a length direction of the gate line GL. For example, the first sub-pixel 12a may be a red sub-pixel or a first color sub-pixel. The second sub-pixel 12b may be a green sub-pixel or a second color sub-pixel. The third sub-pixel 12c may be a blue sub-pixel or a third color sub-pixel. The light emitting device layers disposed in each of the first to third sub-pixels 12a, 12b, and 12c may emit different color light individually or white light in common.

The control circuit 30 may generate a pixel-specific data signal corresponding to each of a plurality of sub-pixels 12a, 12b, and 12c based on an image signal. The control circuit 30 according to an embodiment may calculate red pixel data, green pixel data, and blue pixel data based on an image signal, that is, red input data, green input data, and blue input data of each pixel 12. The control circuit 30 may align the calculated red pixel data, green pixel data, and blue pixel data to suit the pixel arrangement structure and supply the same to the data driving circuit 50.

The control circuit 30 may drive the gate driving circuit 70 and the data driving circuit 50 in a display mode or a sensing mode. The control circuit 30 may generate a data control signal and a gate control signal for driving each of the gate driving circuit 70 and the data driving circuit 50 in a display mode or a sensing mode based on the timing synchronization signal. The control circuit 30 may provide a data control signal to the data driving circuit 50, and may provide a gate control signal to the gate driving circuit 70. For example, the sensing mode (or external compensation driving) may be performed in the inspection process before the product shipment of the light emitting display apparatus, the initial driving of the display panel 10, the power-on of the light emitting display apparatus, the power-off of the light emitting display apparatus, or the blank period of the frame set in real time or periodically.

The control circuit 30 may store pixel-specific sensing data provided from the data driving circuit 50 in the storage circuit according to the sensing mode. In the display mode, the control circuit 30 may correct pixel data to be supplied to each of the sub-pixels 12a, 12b, and 12c based on sensing data stored in the storage circuit, and provide the corrected pixel data to the data driving circuit 50. For example, the pixel-specific sensing data may include change information over time of each of the driving transistor and the light emitting device. Accordingly, in the sensing mode, the control circuit 30 senses a characteristic value (e.g., a threshold voltage or mobility) of the driving transistor disposed in each of the sub-pixels 12a, 12b, and 12c, and correct pixel data to be supplied to each of the sub-pixels 12a, 12b, and 12c based on the sensed value, and thus, deterioration of image quality due to variation in characteristic values of driving transistors in a plurality of sub-pixels may be minimized or prevented.

The data driving circuit 50 may be individually connected to each of the m data lines DL disposed at, in or on the display panel 10. The data driving circuit 50 may receive the pixel-specific data signal and the data control signal provided from the control circuit 30, and may receive a plurality of reference gamma voltages provided from the power supply circuit.

In a display mode, the data driving circuit 50 converts a digital pixel-specific data signal into an analog pixel-specific data voltage using a data control signal and a plurality of reference gamma voltages. In the display mode, the data driving circuit 50 may supply the converted pixel-specific data voltage to the corresponding data line DL, generate a reference voltage synchronized with the data voltage, and supply it to the plurality of reference power lines RL.

In a sensing mode, the data driving circuit 50 converts a digital sensing data signal into a sensing data voltage based on a data control signal and a plurality of reference gamma voltages, and supplies it to the corresponding sub-pixels 12a, 12b, and 12c through the corresponding data line DL. In the sensing mode, the data driving circuit 50 senses a characteristic value of the driving transistor disposed in the corresponding sub-pixels 12a, 12b, and 12c through each of the plurality of reference power lines RL. In the sensing mode, the data driving circuit 50 may provide the sensed sensing data for each pixel to the control circuit 30. For example, the data driving circuit 50 may sequentially sense the first to third sub-pixels 12a, 12b, and 12c constituting the pixel 12.

The gate driving circuit 70 may be individually connected to each of the n gate lines GL provided in the pixel array portion. The gate driving circuit 70 may generate a gate signal according to a predetermined order based on the gate control signal supplied from the control circuit 30 and supply the gate signal to a corresponding gate line GL.

According to an embodiment of the present disclosure, the gate driving circuit 70 may be integrated at one edge and/or both edges of the substrate according to a manufacturing process of the thin film transistor to be connected to a plurality of gate lines GLs in a one-to-one manner. According to another embodiment of the present disclosure, the gate driving circuit 70 may be configured as an integrated circuit and mounted on a substrate, or mounted on a flexible circuit film to be connected to the plurality of gate lines GL in a one-to-one manner.

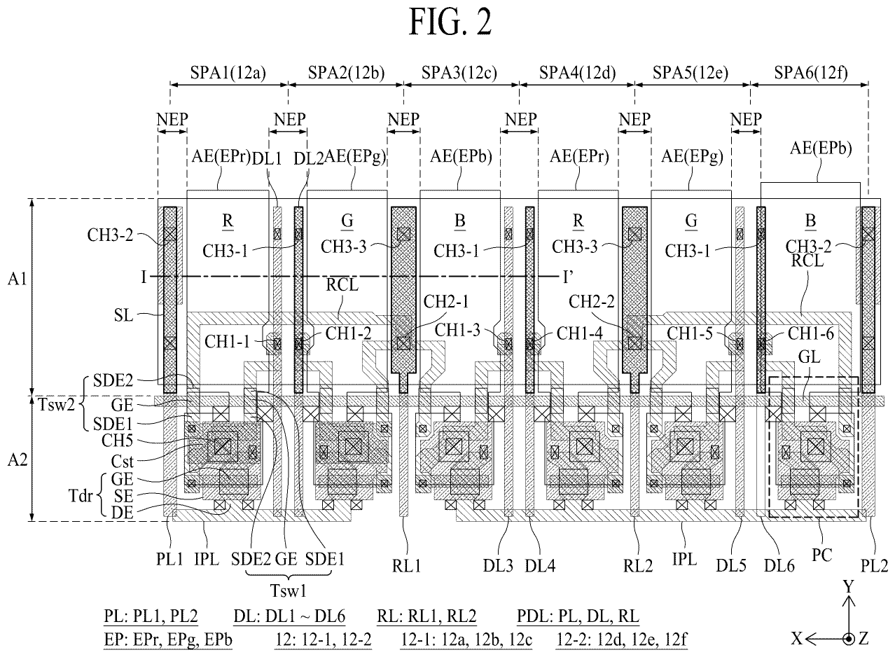

FIG. 2 is a diagram illustrating an arrangement structure of pixels according to an embodiment illustrated in FIG. 1.

Referring to FIG. 2, a light emitting display apparatus according to an embodiment of the present disclosure may include a plurality of pixels 12, a pixel driving line PDL, a gate line GL, an auxiliary line SL, and a pixel circuit PC.

According to an embodiment of the present disclosure, the light emitting display apparatus may include a plurality of pixels 12. For example, two adjacent pixels 12-1 and 12-2 may include a pixel driving line PDL. The two adjacent pixels 12-1 and 12-2 may include a plurality of data lines DL, a plurality of pixel power lines PL, and a plurality of reference power lines RL. The two adjacent pixels 12-1 and 12-2 may include first to sixth data lines DL1 to DL6, first and second pixel power lines PL1 and PL2, and first and second reference power lines RL1 and RL2. The pixel driving line PDL may be disposed on the substrate along the second direction Y. The gate line GL may be disposed on the substrate along the first direction X crossing the second direction Y.

Therefore, hereinafter, for convenience of description, an embodiment of the present disclosure will be described by taking two adjacent pixels 12-1 and 12-2. For example, two adjacent pixels may be a first pixel 12-1 and a second pixel 12-2.

Any one of a plurality of pixels 12 or the first pixel 12-1 may include a plurality of sub-pixel areas SPA1 to SPA3 disposed along the first direction X and the second direction Y crossing the first direction X, and pixel driving lines PDL extending lengthwise along the second direction Y and disposed in a plurality of sub-pixel areas SPA1 to SPA3. Each of a plurality of sub-pixel areas SPA1 to SPA3 or a plurality of sub-pixels 12a, 12b, and 12c may overlap the whole or part of at least one pixel driving line PDL adjacent along the first direction X among the pixel driving line PDL. As another example, each of the plurality of sub-pixel areas SPA1 to SPA3 or the plurality of sub-pixels 12a, 12b, and 12c may be disposed between at least two pixel driving lines PDL adjacent to each other in the first direction X among the pixel driving line PDL. The pixel driving line PDL driving the first pixel 12-1 may be, or may include, the first to third data lines DL1 to DL3, the first pixel power line PL1, and the first reference power line RL1.

The other pixel or the second pixel 12-2 adjacent to each other among the plurality of pixels 12 may include a plurality of sub-pixel areas SPA4 to SPA6 disposed along the first direction X and the second direction Y crossing the first direction X, and pixel driving lines PDL extending lengthwise along the second direction Y and disposed in a plurality of sub-pixel areas SPA4 to SPA6. Each of the plurality of sub-pixel areas SPA4 to SPA6 or the plurality of sub-pixels 12d, 12e, and 12f may overlap the whole or part of at least one pixel driving line PDL adjacent to each other along the first direction X among the pixel driving line PDL. As another example, each of the plurality of sub-pixel areas SPA4 to SPA6 or the plurality of sub-pixels 12d, 12e, and 12f may be disposed between at least two pixel driving lines PDL adjacent to each other in the first direction X among the pixel driving line PDL. The pixel driving line PDL driving the second pixel 12-2 may be, or may include, the fourth to sixth data lines DL4 to DL6, the second pixel power line PL2, and the second reference power line RL2.

A plurality of pixel power lines PL1 and PL2 may be spaced apart from each other on a substrate along the first direction X. A plurality of data lines DL1 to DL6 may be disposed between a plurality of pixel power lines PL1 and PL2 along the first direction X. A plurality of reference power lines RL1 and RL2 may be disposed between a plurality of data lines DL1 to DL6 along the first direction X.

Among the two adjacent pixels 12, the first pixel 12-1 may include a plurality of sub-pixel areas SPA1 to SPA3.

Among a plurality of sub-pixel areas SPA1 to SPA3, the first sub-pixel area SPA1 may be disposed between the first pixel power line PL1 among a plurality of pixel power lines PL and the first data line DL1 among a plurality of data lines DL. For example, the first pixel power line PL1 may be an odd-numbered pixel power line among a plurality of pixel power lines PL.

Among a plurality of sub-pixel areas SPA1 to SPA3, the second sub-pixel area SPA2 may be disposed between a second data line DL2 among a plurality of data lines DL, and a first reference power line RL1 among a plurality of reference power lines RL. For example, among a plurality of data lines DL, the first data line DL1 and the second data line DL2 may be disposed adjacent and parallel to each other. For example, the first reference power line RL1 may be an odd-numbered reference power line among a plurality of reference power lines RL.

Among a plurality of sub-pixel areas SPA1 to SPA3, the third sub-pixel area SPA3 may be disposed between the first reference power line RL1 among the plurality of reference power lines RL, and the third data line DL3 among the plurality of data lines DL.

Among the two adjacent pixels 12, the second pixel 12-2 may include a plurality of sub-pixel areas SPA4 to SPA6.

Among a plurality of sub-pixel areas SPA4 to SPA6, the fourth sub-pixel area SPA4 may be disposed between a fourth data line DL4 among a plurality of data lines DL and a second reference power line RL2 among a plurality of reference power lines RL. For example, among a plurality of data lines DL, a third data line DL3 and a fourth data line DL4 may be disposed adjacent and parallel to each other. For example, the second reference power line RL2 may be an even-numbered reference power line among a plurality of reference power lines RL.

Among the plurality of sub-pixel areas SPA4 to SPA6, the fifth sub-pixel area SPA5 may be disposed between the second reference power line RL2 among the plurality of reference power lines RL and the fifth data line DL5 among the plurality of data lines DL.

Among a plurality of sub-pixel areas SPA4 to SPA6, the sixth sub-pixel area SPA6 may be disposed between the sixth data line DL6 among a plurality of data lines DL and the second pixel power line PL2 among a plurality of pixel power lines PL. For example, among a plurality of data lines DL, the fifth data line DL5 and the sixth data line DL6 may be disposed adjacent and parallel to each other. For example, the second pixel power line RL2 may be an even-numbered pixel power line among a plurality of pixel power lines RL.

Each of a plurality of sub-pixel areas SPA1 to SPA6 may be divided into a first area A1 and a second area A2 based on the second direction Y.

The first area A1 (or light emitting area) may be disposed on an upper side with respect to the second direction Y and may not overlap the gate line GL. The first area A1 of each of the plurality of sub-pixel areas SPA1 to SPA6 may have the same size or different sizes.

A plurality of sub-pixel areas SPA1 to SPA6 may include a light emitting portion EP and a non-light emitting portion NEP disposed in the first area A1. Each of the light emitting portion EP and the non-light emitting portion NEP may be configured to correspond to each of a plurality of sub-pixel areas SPA1 to SPA6.

A plurality of light emitting portions EP of each of the pixels 12-1 and 12-2 may overlap the light emitting device layer. The light emitting device layer disposed on the light emitting portion EP of each of the plurality of sub-pixel areas SPA1 to SPA6 may include an anode electrode AE, a light emitting layer, and a cathode electrode. A plurality of light emitting portions EP of each of the pixels 12-1 and 12-2 may include a first light emitting portion EPr, a second light emitting portion EPg, and a third light emitting portion EPb.

A plurality of non-light emitting portions NEP of each of the pixels 12-1 and 12-2 may overlap the pixel driving line PDL. A plurality of non-light emitting portions NEP of each of the pixels 12-1 and 12-2 may overlap the pixel power line PL, the data line DL, and the reference line RL of the corresponding pixel, respectively. A plurality of non-light emitting portions NEP may be disposed between the light emitting portions EP.

In the first pixel 12-1, the first light emitting portion EPr may be disposed in the first sub-pixel SPA1, the second light emitting portion EPg may be disposed in the second sub-pixel SPA2, and the third light emitting portion EPb may be disposed in the third sub-pixel SPA3.

In the second pixel 12-2, the first light emitting portion EPr may be disposed in the fourth sub-pixel SPA4, the second light emitting portion EPg may be disposed in the fifth sub-pixel SPA5, and the third light emitting portion EPb may be disposed in the sixth sub-pixel SPA6.

The second area A2 (or circuit area) may be disposed at a lower side with respect to the second direction Y and may overlap the gate line GL. The second area A2 of each of the plurality of sub-pixel areas SPA1 to SPA6 may have substantially the same size, but is not limited thereto.

According to an embodiment of the present disclosure, a light emitting display apparatus may include a pixel circuit PC. The pixel circuit PC may be disposed in or overlapped with the second area A2 (or circuit area) of each of the plurality of sub-pixel areas SPA1 to SPA6. The pixel circuit PC may be connected to the pixel driving line PDL and the gate line GL. The pixel circuit PC of each of the plurality of sub-pixel areas SPA1 to SPA6 may include the gate line GL, the pixel power line PL, the data line DL, and the reference power line RL.

The gate line GL may be disposed to be adjacent to the first area A1 among the second areas A2 of the plurality of sub-pixel areas SPA1 to SPA6.

The pixel circuit PC of each of a plurality of sub-pixel areas SPA1 to SPA6 may include a first switching transistor Tsw1, a second switching transistor Tsw2, a driving transistor Tdr, and a storage capacitor Cst. Each of the transistors Tsw1, Tsw2, and Tdr of the pixel circuit PC may be configured of a thin film transistor TFT. For example, at least one of the thin film transistors Tsw1, Tsw2, and Tdr may be an a-Si TFT, a poly-Si TFT, an oxide TFT, or an organic TFT. For example, in the pixel circuit PC, some of the first switching transistor Tsw1, the second switching transistor Tsw2, and the driving transistor Tdr may be thin film transistors including a semiconductor layer (or an active layer) made of low-temperature poly-Si (LTPS) having excellent response characteristics. For example, except for some of the first switching transistor Tsw1, the second switching transistor Tsw2, and the driving transistor Tdr, the rest may be thin film transistors including a semiconductor layer (or active layer) made of oxide having excellent off-current characteristics.

The first switching transistor Tsw1 may include a gate electrode GE, a first source/drain electrode SDE1 connected to the adjacent data line DL, and a second source/drain electrode SDE2 connected to the gate electrode GE of the driving transistor Tdr. The gate electrode GE of the first switching transistor Tsw1 may be a partial area of the gate line GL. The first switching transistor Tsw1 may be turned on according to a first gate signal supplied to the gate line GL to supply a data voltage supplied from the adjacent data line DL to the gate electrode GE of the driving transistor Tdr. In an example, a first source/drain electrode SDE1 may be a source electrode, and a second source/drain electrode SDE2 may be a drain electrode. In another example, a first source/drain electrode SDE1 may be a drain electrode, and a second source/drain electrode SDE2 may be a source electrode.

For example, the first source/drain electrode SDE1 of the first switching transistor Tsw1 disposed in the first sub-pixel area SPA1 may be connected to the first data line DL1 through the 1-1 contact hole CH1-1, and the first source/drain electrode SDE1 of the first switching transistor Tsw1 disposed in the second sub-pixel area SPA2 may be connected to the second data line DL2 through the 1-2 contact hole CH1-2. For example, the first source/drain electrode SDE1 of the first switching transistor Tsw1 disposed in the third sub-pixel area SPA3 may be connected to the third data line DL3 through the 1-3 contact hole CH1-3, and the first source/drain electrode SDE1 of the first switching transistor Tsw1 disposed in the fourth sub-pixel area SPA4 may be connected to the fourth data line DL4 of the 1-4 contact hole CH1-4. For example, the first source/drain electrode SDE1 of the first switching transistor Tsw1 disposed in the fifth sub-pixel area SPA5 may be connected to the fifth data line DL5 through the 1-5 contact hole CH1-5, and the first source/drain electrode SDE1 of the first switching transistor Tsw1 disposed in the sixth sub-pixel area SPA6 may be connected to the sixth data line DL6 through the 1-6 contact hole CH1-6.

The second switching transistor Tsw2 may include a gate electrode GE connected to the gate line GL, a first source/drain electrode SDE1 connected to the source electrode of the driving transistor Tdr, and a second source/drain electrode SDE2 connected to the adjacent reference power line RL. In the display mode, the second switching transistor Tsw2 may supply a reference voltage supplied to the adjacent reference power line RL to the source electrode SE of the driving transistor Tdr according to the gate signal supplied to the gate line GL. In addition, in the sensing mode, the second switching transistor Tsw2 may be turned on by a gate signal supplied to the gate line GL to supply a current output from the driving transistor Tdr to an adjacent reference power line RL or may connect the source electrode SE of the driving transistor Tdr to an adjacent reference power line RL. In each of the plurality of sub-pixel areas SPA1 to SPA6, the gate electrode GE of the second switching transistor Tsw2 may be a partial area of the gate line GL.

The second source/drain electrode SDE2 of the second switching transistor Tsw2 may be electrically connected to the reference power line RL through the reference connection line RCL and the second contact holes CH2-1 and CH2-2. The reference connection line RCL is disposed in parallel with the gate line GL, is disposed to pass through the reference power line RL, and may be electrically connected to the reference power line RL through the second contact holes CH2-1 and CH2-2.

For example, the second source/drain electrode SDE2 of the second switching transistor Tsw2 disposed in the first to third sub-pixel areas SPA1 to SPA3 may be connected to the first reference power line RL1 through the 2-1 contact hole CH2-1. For example, the second source/drain electrode SDE2 of the second switching transistor Tsw2 disposed in the fourth to sixth sub-pixel areas SPA4 to SPA6 may be connected to the second reference power line RL2 through the 2-2 contact hole CH2-2.

The storage capacitor Cst is formed between the gate electrode GE and the source electrode SE of the driving transistor Tdr. For example, the storage capacitor Cst may include a first capacitor electrode made of the gate electrode GE of the driving transistor Tdr, a second capacitor electrode made of the source electrode of the driving transistor Tdr, and a dielectric layer formed in an overlapping area between the first capacitor electrode and the second capacitor electrode. The storage capacitor Cst charges the voltage difference between the gate electrode GE and the source electrode SE of the driving transistor Tdr, and may switch the driving transistor Tdr according to the charged voltage.

The driving transistor Tdr may include a gate electrode GE connected to the second source/drain electrode SDE2 of the first switching transistor Tsw1, a source electrode SE connected to the first source/drain electrode SDE1 of the second switching transistor Tsw2, and a drain electrode DE connected to the pixel power line PL. The driving transistor Tdr may be electrically connected to the light emitting device layer. The source electrode SE and the drain electrode DE of the driving transistor Tdr may be disposed on the same layer as the plurality of data lines DL, the pixel power line PL, and the reference power line RL. The gate electrode GE of the driving transistor Tdr may be disposed on the same layer as the gate line GL. The driving transistor Tdr is turned on by the voltage of the storage capacitor Cst, and thus, an amount of current flowing from the pixel power line PL to the light emitting device layer may be controlled.

Among a plurality of sub-pixel areas SPA1 to SPA6, the drain electrode DE of the driving transistor Tdr disposed in the first and second sub-pixel areas SPA1 and SP2 may be connected to the first pixel power line PL1 through the internal power line IPL. Among a plurality of sub-pixel areas SPA1 to SP6, the drain electrode DE of the driving transistor Tdr disposed in the first and second sub-pixel areas SPA1 and SP2 may protrude from the internal power line IPL. Among the plurality of sub-pixel areas SPA1 to SP6, the drain electrode DE of the driving transistor Tdr disposed in the third to sixth sub-pixel areas SPA3 to SP6 may be connected to the second pixel power line PL2 through the internal power line IPL. Among the plurality of sub-pixel areas SPA1 to SP6, the drain electrode DE of the driving transistor Tdr disposed in the third to sixth sub-pixel areas SPA3 to SP6 may protrude from the internal power line IPL.

According to an embodiment of the present disclosure, the light emitting display apparatus may include an auxiliary line SL. The auxiliary line SL may overlap the pixel driving line PDL. The auxiliary line SL may overlap at least one of the plurality of pixel power lines PL, the plurality of data lines DL, and the plurality of reference power lines RL.

Among the plurality of data lines DL, two adjacent data lines may be configured between two adjacent sub-pixels among the plurality of sub-pixels 12a to 12f. The auxiliary line SL may overlap one or more of the two adjacent data lines.

Among the plurality of data lines DL, a first data line DL1 and a second data line DL2 adjacent to each other may be disposed between the first sub-pixel 12a and the second sub-pixel 12b among the plurality of sub-pixels 12a to 12f. The auxiliary line SL may overlap at least one of the first data line DL1 and the second data line DL2. For example, the auxiliary line SL may overlap the second data line DL2 among the first data line DL1 and the second data line DL2. For another example, the auxiliary line SL may overlap the first data line DL1 among the first data line DL1 and the second data line DL2.

Among the plurality of data lines DL, a third data line DL3 and a fourth data line DL4 adjacent to each other may be disposed between the third sub-pixel 12c and the fourth sub-pixel 12d among the plurality of sub-pixels 12a to 12f. The auxiliary line SL may overlap at least one of the third data line DL3 and the fourth data line DL4. For example, the auxiliary line SL may overlap the fourth data line DL4 among the third data line DL3 and the fourth data line DL4. For another example, the auxiliary line SL may overlap the third data line DL3 among the third data line DL3 and the fourth data line DL4.

Among the plurality of data lines DL, an adjacent fifth data line DL5 and a sixth data line DL6 may be disposed between the fifth sub-pixel 12e and the sixth sub-pixel 12f among the plurality of sub-pixels 12a to 12f. The auxiliary line SL may overlap at least one of the fifth data line DL5 and the sixth data line DL6. For example, the auxiliary line SL may overlap the sixth data line DL6 among the fifth data line DL5 and the sixth data line DL6. For another example, the auxiliary line SL may overlap the fifth data line DL5 among the fifth data line DL5 and the sixth data line DL6.

Each of the auxiliary line SL and the plurality of data lines DL may be electrically connected through a 3-1 contact hole CH3-1. According to an embodiment of the present disclosure, since the auxiliary line SL and the plurality of data lines DL are electrically connected, resistance of each of the plurality of data lines DL may be reduced.

The plurality of pixel power lines PL may be configured in each of the plurality of pixels. The auxiliary line SL may overlap each of the plurality of pixel power lines PL. An auxiliary line SL may be disposed in an upper portion of the plurality of pixel power lines PL, respectively. An auxiliary line SL may be disposed in an upper portion of the first pixel power line PL1. The first pixel power line PL1 may overlap the auxiliary line SL. An auxiliary line SL may be disposed in an upper portion of the second pixel power line PL2. The second pixel power line PL2 may overlap the auxiliary line SL.

The pixel power line PL and the auxiliary line SL on the pixel power line PL may be electrically connected through a 3-2 contact hole CH3-2. According to an embodiment of the present disclosure, since the auxiliary line SL and the pixel power line PL are electrically connected, resistance of each of the plurality of pixel power lines PL may be reduced.

A plurality of reference power lines RL may be configured in each of a plurality of pixels. The auxiliary line SL may overlap each of a plurality of reference power lines RL. An auxiliary line SL may be disposed above a respective one of a plurality of reference power lines RL. An auxiliary line SL may be disposed above the first reference power line RL1. The first reference power line RL1 may overlap the auxiliary line SL. An auxiliary line SL may be disposed above the second reference power line RL2. The second reference power line RL2 may overlap the auxiliary line SL.

The reference power line RL and the auxiliary line SL on the reference power line RL may be electrically connected through a 3-3 contact hole CH3-3. According to an embodiment of the present disclosure, since the auxiliary line SL and the reference power line RL are electrically connected, resistance of each of the plurality of reference power lines RL may be reduced.

According to an embodiment of the present disclosure, the auxiliary line SL is disposed on the pixel driving line PDL, and the auxiliary line SL disposed on the pixel driving line PDL is electrically connected to each of the pixel driving lines PDL, so that the resistance of the pixel driving line PDL may be reduced.

The auxiliary line SL may be disposed on the same layer as the gate electrode GE and the gate line GL. The auxiliary line SL includes the same material as the gate electrode GE and the gate line GL, and may be configured by using the same mask process. Accordingly, the light emitting display apparatus may arrange the auxiliary line SL on the pixel driving line PDL without a separate mask process.

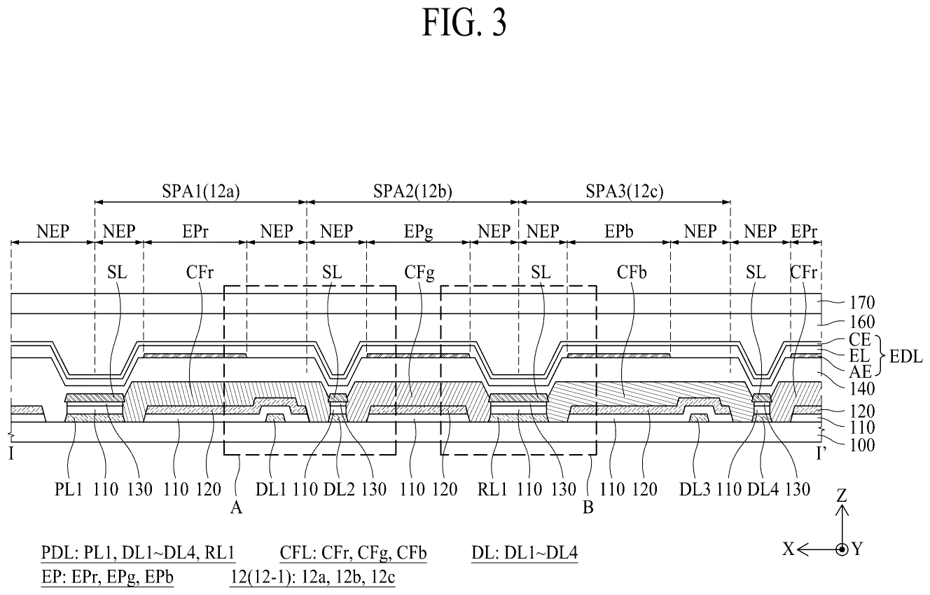

According to an embodiment of the present disclosure, the pixel driving line PDL and the source/drain electrodes of the transistors Tsw1, Tsw2, and Tdr may be disposed on a substrate. The buffer layer may be disposed on the pixel driving line PDL and the source/drain electrodes of the transistors Tsw1, Tsw2, and Tdr. The semi-conductor layer may have a source area, a drain area, and a channel area of the semi-conductor layer, and a channel area of the semi-conductor layer may be covered by an insulating layer. Each of the gate line GL, the gate electrode GE, and the auxiliary line SL may be disposed on the insulating layer. The auxiliary line SL may separate the color filter layer disposed after the auxiliary line SL for each pixel, and generate a groove in the overcoat layer. The pixel driving line PDL, the source/drain electrode of the transistors Tsw1, Tsw2, and Tdr, the gate line GL, the gate electrode GE, and the auxiliary line SL may be covered by the passivation layer and the overcoat layer. In the first area A1, a color filter layer may be configured between the passivation layer and the overcoat layer. A light emitting device layer including the anode AE connected to the transistors Tsw1, Tsw2, and Tdr may be configured on the overcoat layer. The configuration and effects of the auxiliary line and the groove of the light emitting display apparatus according to an embodiment of the present disclosure will be described in detail with reference to FIGS. 3 to 5 below.

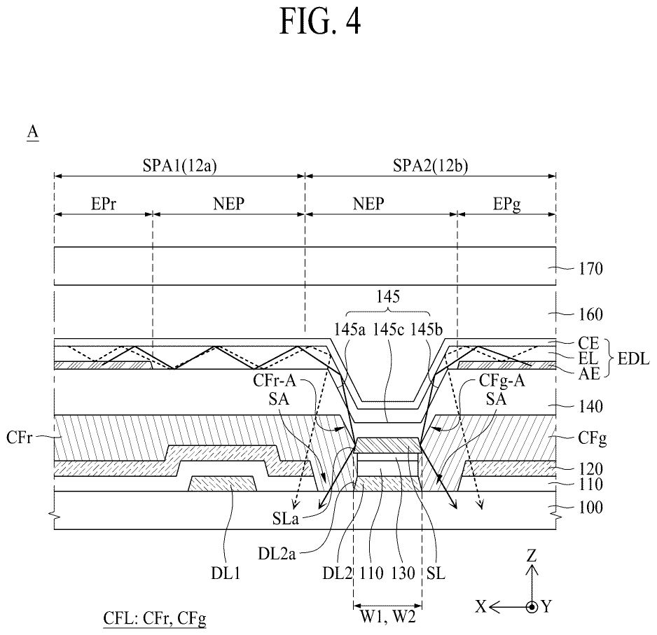

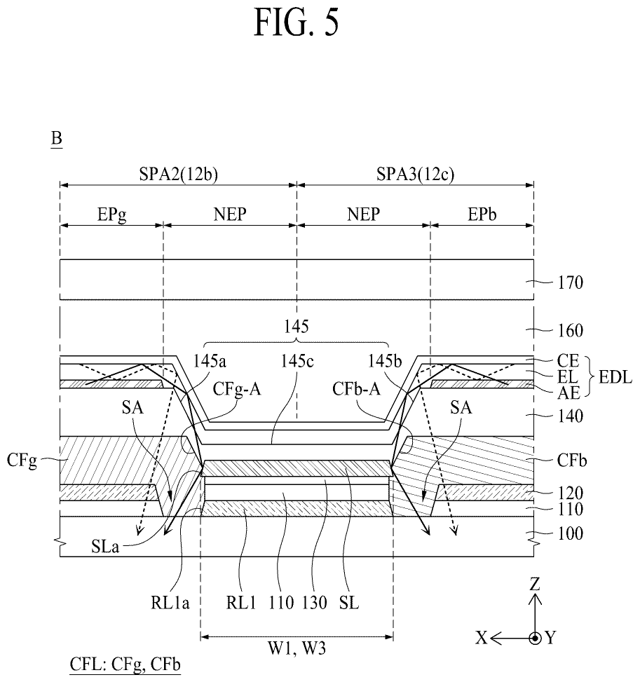

FIG. 3 is a cross-sectional view taken along the line I-I′ shown in FIG. 2. FIG. 4 is a cross-sectional view illustrating an example of an area A shown in FIG. 3. FIG. 5 is a cross-sectional view illustrating an example of area B shown in FIG. 3. This is a cross-sectional view of one pixel in a light emitting display apparatus according to an embodiment of the present disclosure described with reference to FIGS. 1 and 2. Therefore, hereinafter, substantially the same reference numerals are assigned to substantially the same configuration, and overlapping descriptions are briefly described or omitted. Thus, repetitive descriptions of the same or similar elements may be omitted for brevity, and the descriptions provided for elements in one or more figures may also apply to elements in other figures that use the same or similar reference numerals unless stated otherwise.

Referring to FIGS. 3 to 5, a light emitting display apparatus according to an embodiment of the present disclosure may include a substrate 100, a pixel driving line PDL, a buffer layer 110, an insulating layer 130, an auxiliary line SL, a passivation layer 120, a color filter layer CFL, an overcoat layer 140, a groove 145, and a light emitting device layer EDL.

The substrate 100 includes a transistor and may be a transistor array substrate, a lower substrate, a base substrate, or a first substrate. The substrate 100 may be a transparent glass substrate or a transparent plastic substrate.

The light emitting display apparatus, the display panel 10, or the substrate 100 may include a plurality of pixels 12. Each of a plurality of pixels 12 may include a plurality of sub-pixels 12a, 12b, and 12c. A plurality of sub-pixels 12a, 12b, and 12c may be a first sub-pixel 12a, a second sub-pixel 12b, and a third sub-pixel 12c.

Each of a plurality of sub-pixels 12a, 12b, and 12c may include a light emitting portion EP and a non-light emitting portion NEP. The light emitting portion EP may overlap the light emitting device layer EDL. The non-light emitting portion NEP may overlap the pixel driving line PDL. For example, in the first pixel area SPA1, the non-light emitting portion NEP may overlap the first pixel power line PL1 and the first data line DL1. In the second pixel area SPA2, the non-light emitting portion NEP may overlap the second data line DL2 and the first reference power line RL1. In the third pixel area SPA3, the non-light emitting portion NEP may overlap the first reference power line RL1 and the third data line DL3.

In one pixel 12-1, the pixel driving line PDL may include a pixel power line PL1, a plurality of data lines DL, and a reference power line RL1. The pixel power line PL1, a plurality of data lines DL, and the reference power line RL1 may be disposed in parallel in the second direction Y on the substrate 100. For example, in one pixel 12-1, the pixel power line PL1 and the reference power line RL1 may be spaced apart from each other and configured in parallel. In one pixel 12-1, a plurality of data lines DL may be provided between the pixel power line PL1 and the reference power line RL1.

The pixel power line PL1, a plurality of data lines DL, and the reference power line RL1 may be disposed on the same layer. The pixel power line PL1, a plurality of data lines DL, and the reference power line RL1 include the same material and may be formed by using the same process. For example, the pixel power line PL1, the plurality of data lines DL, and the reference power line RL1 may include molybdenum (Mo), aluminum (Al), chromium (Cr), gold (Au), titanium (Ti), nickel (Ni), neodymium (Nd), copper (Cu), tungsten (W), or a compound or alloy thereof, and may be formed of a single layer of the metal or alloy or a multilayer of two or more layers. For example, the pixel power line PL1, a plurality of data lines DL, and the reference power line RL1 may be formed of two or more layers such as Cu/MoTi. For example, the pixel power line PL1, a plurality of data lines DL, and the reference power line RL1 may be formed of two or more layers including a low-reflective material such as tungsten (W) oxide.

The buffer layer 110 may be formed on the substrate 100. The buffer layer 110 may be disposed on each of the light emitting portion EP and the non-light emitting portion NEP of the substrate 100.

According to an embodiment of the present disclosure, the buffer layer 110 may be configured on the entire surface of the light emitting portion EP. The buffer layer 110 may cover the pixel driving line PDL disposed on the non-emission portion NEP. The buffer layer 110 may cover a front surface of the pixel driving line PDL that does not overlap the auxiliary line SL among the pixel driving lines PDL. The buffer layer 110 may cover a top surface of the pixel driving line PDL, which overlaps the auxiliary line SL among the pixel driving lines PDL. The buffer layer 110 may cover a top surface of the first data line DL1 on which the auxiliary line SL is not formed. The buffer layer 110 may cover a top surface of the second data line DL2 in which the auxiliary line SL is formed thereon.

Accordingly, a spaced area SA in which the buffer layer 110 is not formed may be disposed between the first data line DL1 on which the auxiliary line SL is not formed and the second data line DL2 on which the auxiliary line SL is formed. The spaced area SA may be an area in which the buffer layer 110 is not formed on the upper surface of the substrate 100. The spaced area SA may be an area in contact with a color filter layer CFL to be described later.

The buffer layer 110 may block a material contained in the substrate 100 from being diffused into the active layer of the transistor during a high-temperature process during a manufacturing process of the thin film transistor. For example, the buffer layer 110 may include an inorganic material such as silicon oxide (SiOx) or silicon nitride (SiNx).

The insulating layer 130 may be disposed on the non-emission portion NEP. The insulating layer 130 may be disposed between the auxiliary line SL and the pixel driving line PDL. The insulating layer 130 may be disposed between the buffer layer 110 and the auxiliary line SL. The insulating layer 130 may be formed in an island shape under the auxiliary line SL. The insulating layer 130 may be disposed on the same layer as the gate insulating layer formed in an island shape under the gate electrode. The insulating layer 130 includes the same material as the gate insulating layer, and may be formed using the same process.

The buffer layer 110 and the insulating layer 130 may have a width smaller than that of the pixel driving line PDL. The buffer layer 110 and the insulating layer 130 may have a width smaller than that of the bottom surface of the pixel driving line PDL. The buffer layer 110 and the insulating layer 130 may have a width smaller than that of the auxiliary line SL. The buffer layer 110 and the insulating layer 130 may have a width smaller than that of the bottom surface of the auxiliary line SL.

According to an embodiment of the present disclosure, the buffer layer 110 and the insulating layer 130 have a width smaller than that of the auxiliary line SL, and thus the buffer layer 110, the insulating layer 130, and the auxiliary line SL may have an undercut shape. Accordingly, the color filters CFr, CFg, and CFb formed in each sub-pixel may be easily separated in a subsequent process. For example, the color filters CFr, CFg, and CFb of the adjacent color filter layer CFL may be spaced apart from each other by the auxiliary line SL. The color filters CFr, CFg, and CFb of the adjacent color filter layer CFL may not be in contact with each other by the auxiliary line SL.

The auxiliary line SL may be disposed on the substrate 100 along the second direction Y. The auxiliary line SL may be disposed on the pixel driving line PDL. The auxiliary line SL may overlap the pixel driving line PDL. The auxiliary line SL may overlap at least one of the plurality of data lines DL, the pixel power line PL, and the reference power line RL. The auxiliary line SL may overlap one data line DL2 among the plurality of data lines DL, the first pixel power line PL1, and the first reference power line RL2, respectively. For example, there may be a plurality of auxiliary lines SL, and each of the plurality of auxiliary lines SL may overlap one data line DL2 among the plurality of data lines DL, the first pixel power line PL1, and the first reference power line RL1, respectively. Accordingly, the auxiliary line SL may be disposed between each of the sub-pixel areas SPA1 to SPA3.

The auxiliary line SL may have the same width as the pixel driving line PDL. For example, the width of the auxiliary line SL disposed on the first pixel power line PL1 may be the same as the width of the first pixel power line PL1. The width W1 of the auxiliary line SL disposed on the second data line DL2 may be the same as the width W2 of the second data line DL2. The width W1 of the auxiliary line SL disposed on the first reference power line RL1 may be the same as the width W3 of the first reference power line RL1.

The auxiliary line SL may have the same shape as the pixel driving line PDL. For example, the auxiliary line SL and the pixel driving line PDL may have an inclined surface having a width of an upper surface smaller than a width of a lower surface and an inclined side surface. For example, the auxiliary line SL and the pixel driving line PDL may have a tapered shape.

According to an embodiment of the present disclosure, the light emitting display apparatus includes an auxiliary line SL and a pixel driving line PDL having the same width and tapered shape, and thus the color filter layer CFL disposed later may easily contact the side surfaces of each of the auxiliary line SL and the pixel driving line PDL, and the end of the color filter layer CFL may be configured to have an inclined surface.

Further, according to an embodiment of the present disclosure, the light emitting display apparatus may include an auxiliary line SL and a pixel driving line PDL having the same width and tapered shape. Accordingly, when the light emitted from the light emitting layer EL is reflected by the cathode electrode CE and travels in the lower direction, the light may not travel to the adjacent pixel area, but may be reflected back to the side surface of the auxiliary line SL to emit light to the corresponding pixel area. Accordingly, light extraction efficiency of the light emitting display apparatus may be improved.

The passivation layer 120 may be disposed on the buffer layer 110. The passivation layer 120 may cover the pixel driving line PDL that does not overlap the auxiliary line SL. The passivation layer 120 may cover the first data line DL that does not overlap the auxiliary line SL. The passivation layer 120 may not be formed on an upper portion of the auxiliary line SL. The passivation layer 120 may be spaced apart from the auxiliary line SL. The passivation layer 120 may not be formed on upper portions of the second data line DL2, the first pixel power line SL1, and the first reference power line RL1 overlapping the auxiliary line SL. The passivation layer 120 may not be formed in the spaced area SA on the substrate 100. The passivation layer 120 may be disposed in each of the plurality of sub-pixel areas SPA1 to SPA3 with the auxiliary line SL interposed therebetween. Accordingly, the end of the color filter layer CFL, which is to be later configured, may cover the spaced area SA.

The color filter layer CFL may be disposed between the substrate 100 and the overcoat layer 140. The color filter layer CFL may be interposed between the passivation layer 120 and the overcoat layer 140. The color filter layer CFL may be disposed to overlap the light emitting portions EPr, EPb, and EPg of a plurality of sub-pixel areas SPA1 to SPA3. The color filter layer CFL may have a size larger than a size of the light emitting portions EPr, EPb, and EPg of each of a plurality of sub-pixel areas SPA1 to SPA3. Accordingly, both ends of the color filter layer CFL may be disposed on the non-light emitting portion NEP.

The color filter layer CFL may include a red color filter CFr overlapping the red emission portion EPr of the first sub-pixel area SPA1, a green color filter CFg overlapping the green emission portion EPg of the second sub-pixel area SPA2, and a blue color filter CFb overlapping the blue emission portion EPb of the third sub-pixel area SPA3.

Each of the red color filter CFr, the green color filter CFg, and the blue color filter CFb may have a size larger or wider than that of the corresponding light emitting portions EPr, EPg, and EPb. For example, each of the red color filter CFr, green color filter CFg, and blue color filter CFb may have a larger or wider size than the corresponding light emitting portions EPr, EPg, and EPb to prevent light leakage from entering from other adjacent sub-pixel areas.

According to an embodiment of the present disclosure, ends of each of the red color filter CFr, the green color filter CFg, and the blue color filter CFb may cover a side surface of the pixel driving line PDL and a side surface of the auxiliary line SL adjacent to each other with the corresponding light emitting portions EPr, EPg, and EPb interposed therebetween. Accordingly, the color filters CFr, CFg, and CFb disposed in each of the pixel areas SPA1 to SPA3 may be spaced apart from each other with the auxiliary line SL interposed therebetween.

One end of the red color filter CFr may cover a side surface of the first pixel power line PL1 and a side surface of the auxiliary line SL disposed on the first pixel power line PL1. The other end of the red color filter CFr may cover a side surface of the second data line DL and a side surface of the auxiliary line SL disposed on the second data line DL2.

One end of the green color filter CFg may cover a side surface of the second data line DL2 and a side surface of the auxiliary line SL disposed on the second data line DL2. The other end of the green color filter CFg may cover a side surface of the first reference power line RL1 and a side surface of the auxiliary line SL disposed on the first reference power line RL1.

One end of the blue color filter CFb may cover a side surface of the first reference power line RL1 and a side surface of the auxiliary line SL disposed on the first reference power line RL1. The other end of the blue color filter CFb may cover a side surface of the fourth data line DL4 of the adjacent pixel and a side surface of the auxiliary line SL disposed on the fourth data line DL4.

Each of the red color filter CFr, the green color filter CFg, and the blue color filter CFb may cover the spaced area SA between the passivation layer 120 and the pixel driving line PDL, which are spaced apart from each other. Accordingly, ends of each of the red color filter CFr, the green color filter CFg, and the blue color filter CFb may partially contact the upper surface of the substrate 100. In addition, the ends of each of the red color filter CFr, the green color filter CFg, and the blue color filter CFb may have an inclined surface CFr-A, CFg-A, and CFb-A.

The auxiliary line SL and the pixel driving line PDL may protrude in the direction of the color filter layer CFL rather than the buffer layer 110 and the insulating layer 130 disposed between the auxiliary line SL and the pixel driving line PDL.

For example, an end of the first pixel power line PL1 adjacent to the red color filter CFr and an end of the auxiliary line SL disposed on the first pixel power line PL1 may include a protrusion protruding in the direction of the red color filter CFr.

Both ends of the second data line DL2 adjacent to the red color filter CFr and the green color filter CFg, and both ends of the auxiliary line SL disposed on the second data line DL2 may include respective protrusions DL2a and SLa protruding in the direction of the red color filter CFr and the green color filter CFg, respectively.

Both ends of the first reference power line RL1 adjacent to the green color filter CFg and the blue color filter CFb, and both ends of the auxiliary line SL disposed on the first reference power line RL1 may include respective protrusion portions RL1a and SLa protruding in the direction of the green color filter CFg and the blue color filter CFb, respectively.

Accordingly, the auxiliary line SL and the pixel driving line PDL may have an undercut shape. Accordingly, each of the red color filter CFr, the green color filter CFg, and the blue color filter CFb may be inserted into the side surfaces of the insulating layer 130 and the buffer layer 110 disposed between the auxiliary line SL and the driving line PDL. Accordingly, ends of each of the red color filter CFr, the green color filter CFg, and the blue color filter CFb may have an inclined surface, and may be easily spaced apart from each other with the auxiliary line SL interposed therebetween. In addition, an overcoat layer 140 to be described later may be disposed along the shape of the inclined surface included in each of the red color filter CFr, the green color filter CFg, and the blue color filter CFb.

According to an embodiment of the present disclosure, the red color filter CFr, the green color filter CFg, and the blue color filter CFb may each include quantum dots having a size that re-emit light according to light emitted from the light emitting device layer EDL toward the substrate 100 to emit light of a color set in a sub-pixel. In this case, the red color filter CFr may further include a long-wavelength absorbing material (or dye) that does not contain red quantum dots or absorbs at least a part of long-wavelength light so that transmittance (or emission rate) of light in a long-wavelength area can be reduced. For example, the long-wavelength absorbing material may absorb wavelengths of 620 nm to 700 nm, thereby reducing transmittance (or emission rate) of light in a long-wavelength area, thereby increasing a color temperature.

The overcoat layer 140 may be formed on the substrate 100. The overcoat layer 140 may cover the passivation layer 120 and the color filter layer CFL. The overcoat layer 140 may cover the pixel driving line PDL and the auxiliary line SL. The overcoat layer 140 may be formed on the pixel circuit while covering the pixel circuit including the transistor. The overcoat layer 140 may be formed along the shape of the upper surface of the color filter layer CFL and the auxiliary line SL. The overcoat layer 140 may be formed along the upper surface of the color filter layer CFL disposed in the light emitting portion EP and the inclined surfaces CFr-A, CFg-A, and CFb-A of the color filter layer CFL disposed in the non-light emitting portion NEP. Accordingly, a groove 145 may be formed on the upper portion of the auxiliary line SL disposed in the non-light emitting portion NEP.

The groove 145 may be disposed in the non-light emitting portion NEP of the substrate 100. The groove 145 may overlap the end of the color filter layer CFL and the auxiliary line SL. The groove 145 is formed in the overcoat layer 140 and may have a concave shape from an upper surface to a lower surface of the overcoat layer 140. The groove 145 may be formed along the end of the color filter layer CFL and the auxiliary line SL. Accordingly, the groove 145 may include at least two inclined portions 145a and 145b and a connection portion 145c connecting at least two inclined portions. At least one of the two or more inclined portions 145a and 145b may overlap ends of the adjacent color filters CFr, CFg, and CFb.

According to an embodiment of the present disclosure, the groove 145 may include a first slope portion 145a, a second slope portion 145b, and a first connection portion 145c. In one or more examples, a first slope portion may be referred to as a first inclined portion and vice versa; a second slope portion may be referred to as a second inclined portion and vice versa.

In the first pixel area SPA1 and the second pixel area SPA2, the first inclined portion 145a may overlap the red color filter CFr. For example, the red color filter CFr may be configured to fill the spaced area SA between the passivation layer 120 and the second data line DL2, and cover one side surface of the second data line DL2 and the auxiliary line SL. Accordingly, the red color filter CFr may have an inclined surface CFr-A overlapping the spaced area SA between the passivation layer 120 and the second data line DL2. Since the overcoat layer 140 is configured along the color filter layer CFL and the auxiliary line SL, the first inclined portion 145a of the groove 145 may be configured to correspond to the inclined surface CFr-A of the red color filter CFr.

In the first pixel area SPA1 and the second pixel area SPA2, the second inclined portion 145b may overlap the green color filter CFg. For example, the green color filter CFg may be configured to fill the spaced area SA between the passivation layer 120 and the second data line DL2, and cover the other side surfaces of the second data line DL2 and the auxiliary line SL. Accordingly, the green color filter CFg may have an inclined surface CFg-A overlapping the spaced area SA between the passivation layer 120 and the second data line DL2. Since the overcoat layer 140 is configured along the color filter layer CFL and the auxiliary line SL, the second inclined portion 145b may be configured to correspond to the inclined surface CFg-A of the green color filter CFg.

In the first pixel area SPA1 and the second pixel area SPA2, the first connection portion 145c may connect the first and second inclined portions 145a and 145b. The first connection portion 145c may overlap the auxiliary line SL. The first connection portion 145c may overlap the driving power line PDL or the second data line DL2.

In the second pixel area SPA2 and the third pixel area SPA3, the first inclined portion 145a may overlap the green color filter CFg. For example, the green color filter CFg may be configured to fill the spaced area SA between the passivation layer 120 and the first reference power line RL1, and cover one side surface of the first reference power line RL1 and the auxiliary line SL. Accordingly, the green color filter CFg may have an inclined surface CFg-A overlapping the spaced area SA between the passivation layer 120 and the first reference power line RL1. Since the overcoat layer 140 is configured along the color filter layer CFL and the auxiliary line SL, the first inclined portion 145a may be configured to correspond to the inclined surface CFg-A of the green color filter CFg.

In the second pixel area SPA2 and the third pixel area SPA3, the second inclined portion 145a may overlap the blue color filter CFb. For example, the blue color filter CFb may be configured to fill the spaced area SA between the passivation layer 120 and the first reference power line RL1, and cover the other side surfaces of the first reference power line RL1 and the auxiliary line SL. Accordingly, the blue color filter CFb may have an inclined surface CFb-A overlapping the spaced area SA between the passivation layer 120 and the first reference power line RL1. Since the overcoat layer 140 is configured along the color filter layer CFL and the auxiliary line SL, the second inclined portion 145b may be configured to correspond to the inclined surface CFb-A of the blue color filter CFb.

In the second pixel area SPA2 and the third pixel area SPA3, the first connection portion 145c may connect the first and second inclined portions 145a and 145b. The first connection portion 145c may overlap the auxiliary line SL. The first connection portion 145c may overlap the driving power line PDL or the first reference line RL1.

According to an embodiment of the present disclosure, the groove 145 may be formed along the shapes of the color filter layer CFL and the auxiliary line SL without using a separate mask process (or a halftone mask process). Thereafter, due to the cathode electrode formed along the groove 145, the light emitting display apparatus of the present disclosure may have a mirror structure in which light extraction efficiency of the light emitting display apparatus can be improved without an increase in a manufacturing process and cost.

The light emitting device layer EDL may be disposed on the overcoat layer 140. The light emitting device layer EDL may be configured on the light emitting portion EP of each of a plurality of sub-pixel areas SPA1 to SPA3. The light emitting device layer EDL may be connected to a pixel circuit. The light emitting device layer EDL may include an anode electrode AE, a light emitting layer EL, and a cathode electrode CE.

The anode electrode AE may be individually disposed on the overcoat layer 140 on the substrate 100 corresponding to the light emitting portion EP of each of the plurality of sub-pixel areas SPA1 to SPA3. According to an example, the anode electrode AE may have a size and shape corresponding to the light emitting portion EP of each of the plurality of sub-pixel areas SPA1 to SPA3. The anode electrode AE may be made of a transparent conductive material such as a transparent conductive oxide (TCO) so that light emitted from the light emitting layer EL may be transmitted to the outside.

The anode electrode AE may be in direct contact with the uppermost surface of the overcoat layer 140. For example, the anode electrode AE may be configured in a shape following the morphology of the overcoat layer 140. For example, the anode electrode AE of each of a plurality of sub-pixel areas SPA1 to SPA3 may include an extension portion extending toward a corresponding pixel circuit. The extension portion of the anode electrode AE may be electrically connected to the source or drain electrode of the driving transistor of the corresponding pixel circuit through an electrode contact hole disposed in the overcoat layer 140 and the passivation layer 120. Accordingly, the anode electrode AE of each of the plurality of sub-pixel areas SPA1 to SPA3 may individually receive a data current from a driving transistor of a corresponding pixel circuit.

The anode electrode AE may be spaced apart from the groove 145. The anode electrode AE may not be formed in the groove 145. Accordingly, light emitted from the light emitting layer EL may be reflected by the cathode electrode CE and easily emitted in a downward direction.

The light emitting layer EL of the light emitting device layer EDL may be configured on the entire surfaces of the first to third sub-pixel areas SPA1 to SPA3. The light emitting layer EL may be configured on the anode electrode AE, the overcoat layer 140, and the groove 145 in each of the first to third sub-pixel areas SPA1 to SPA3.

The light emitting layer EL may be an organic light emitting device, a quantum dot light emitting device, an inorganic light emitting device, or a micro light emitting diode device. For example, the light emitting layer EL made of the organic light emitting device may include a hole functional layer disposed on the anode electrode, an organic light emitting layer disposed on the hole functional layer, and an electronic functional layer disposed on the organic light emitting layer.

According to an embodiment of the present disclosure, the light emitting layers EL disposed in each of the first to third sub-pixel areas SPA1 to SPA3 may be disposed to emit light of different colors. For example, the light emitting layer EL of the first sub-pixel area SPA1 may include a red organic light emitting layer, the light emitting layer EL of the second sub-pixel area SPA2 may include a green organic light emitting layer, and the light emitting layer EL of the third sub-pixel area SPA3 may include a blue organic light emitting layer.

According to another example, the light emitting layers EL disposed in each of the first to third sub-pixel areas SPA1 to SPA3 may be disposed as a common layer emitting white light. For example, the light emitting layers EL disposed in each of the first to third sub-pixel areas SPA1 to SPA3 may include a first organic light emitting layer and the second organic light emitting layer or may include the first organic light emitting layer, the second organic light emitting layer, and the third organic light emitting layer. In this case, the light emitting layer EL may be in direct contact with the anode electrode AE disposed in each of the first to third sub-pixel areas SPA1 to SPA3.

Additionally, the emitting layer EL disposed in each of the first to third sub-pixel areas SPA1 to SPA3 may be changed to a quantum dot light emitting device or may further include a quantum dot emitting layer to improve color reproduction.

The cathode electrode CE of the light emitting device layer EDL may be disposed on the entire display area of the substrate 100 to be in direct contact with the light emitting layer EL. The cathode electrode CE according to an example may include a metal material having a high reflectivity to reflect light emitted and incident from the emission layer EL toward the substrate 100.

The light emitting layer EL and the cathode electrode CE may overlap the groove 145. The light emitting layer EL and the cathode electrode CE may be configured according to a shape of the groove 145. Accordingly, the light emitting layer EL and the cathode electrode CE overlapping the groove 145 may have at least two inclined portions and a connection portion connecting at least two inclined portions. For example, some of the light emitted from the light emitting layer EL may be primarily reflected by the cathode electrode CE overlapping the groove 145. A portion of the light primarily reflected by the cathode electrode CE may pass through the color filter layer CFL and emit light in a direction of the substrate 100. The remaining portion of the light primarily reflected by the cathode electrode CE may be secondarily reflected by the auxiliary line SL. Light secondarily reflected by the auxiliary line SL is changed in an optical path, and may pass through the color filter layer CFL and emit light in a direction of the substrate 100.

According to an embodiment of the present disclosure, since the light emitting display apparatus includes an auxiliary line SL and a groove 145 overlapping the pixel driving line PDL, may be formed between each sub-pixel without adding a separate mask process. Accordingly, since a reflection direction of light toward adjacent sub-pixels may be controlled with a corresponding pixel, light extraction efficiency of the light emitting display apparatus may be improved.

According to an embodiment of the present disclosure, since the light emitting display apparatus includes an auxiliary line SL and a groove 145 overlapping the pixel driving line PDL, light may be extracted even in the non-emission area. Accordingly, compared to a display apparatus without an auxiliary line and a groove, the light emission efficiency may be improved with the same or higher efficiency even at lower power. Accordingly, overall power consumption may be reduced.

According to an embodiment of the present disclosure, since the light emitting display apparatus includes an auxiliary line SL and a groove 145 overlapping the pixel driving line PDL, light dissipated by the wave guide and light reflected from inside the substrate and dissipated may be emitted to the outside. Accordingly, light extraction efficiency can be maximized.

According to one or more embodiments of the present disclosure, since the light emitting display apparatus includes the auxiliary line SL and the groove 145 overlapping the pixel driving line PDL, a groove may be formed between each sub-pixel without adding a separate mask process (e.g., a halftone mask process or the like). Accordingly, light extraction efficiency of the light emitting display apparatus may be improved without increasing a manufacturing process and a cost.

According to an embodiment of the present disclosure, the light emitting display apparatus may further include an encapsulation layer 160. The encapsulation layer 160 may be formed on the display area of the substrate 100 to cover the cathode electrode CE. The encapsulation layer 160 may protect the thin film transistor, the light emitting layer EL and the like from an external impact, and may prevent oxygen, moisture, and particles from penetrating into the light emitting device layer EDL. For example, the encapsulation layer 160 may include at least one inorganic layer. For example, the encapsulation layer 160 may further include at least one organic layer. For example, the encapsulation layer 160 may include a first inorganic encapsulation layer, an organic encapsulation layer, and a second inorganic encapsulation layer, but is not limited thereto.

Selectively, the encapsulation layer 160 may be changed into a filler surrounding the entire pixel. In this case, the light emitting display apparatus according to an embodiment of the present disclosure may further include an encapsulation substrate 170 attached onto the substrate 100 via a filler. The encapsulation substrate 170 may be formed of a plastic material, or a glass material. For example, the filler may include a getter material that absorbs oxygen or/and moisture, but is not limited thereto.

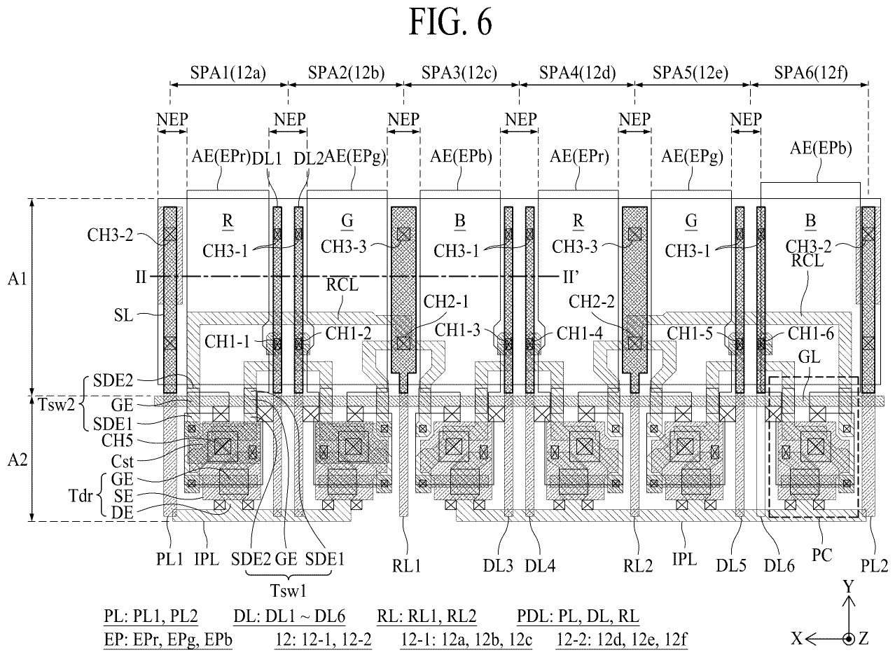

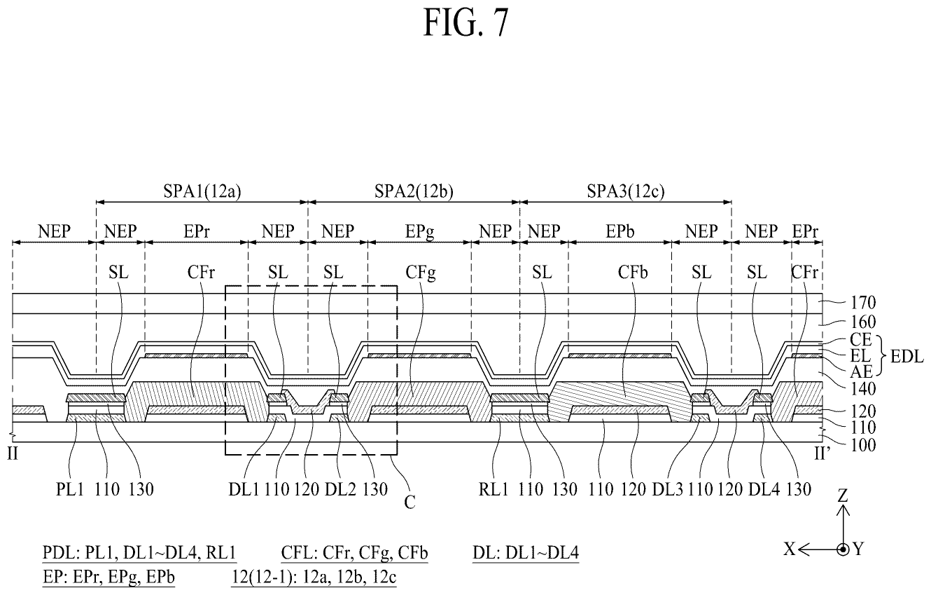

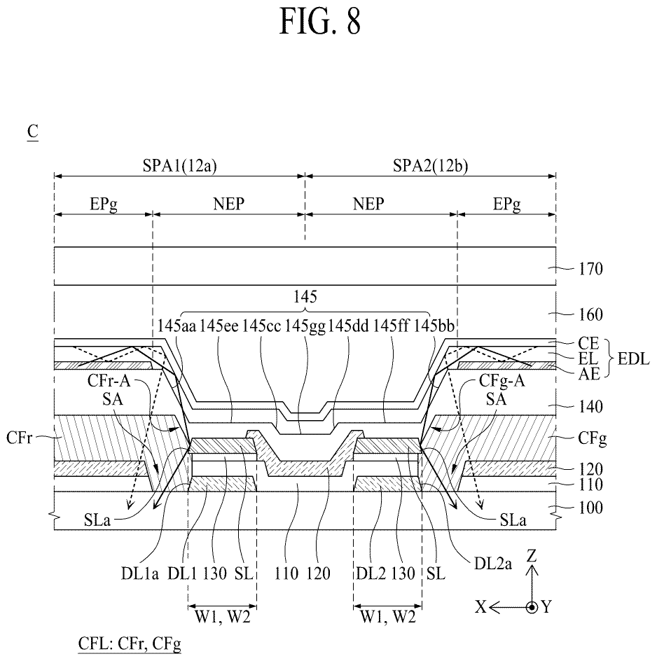

FIG. 6 is a diagram illustrating an arrangement structure of pixels according to another embodiment illustrated in FIG. 1. FIG. 7 is a cross-sectional view taken along the line II-II′ shown in FIG. 6. FIG. 8 is a cross-sectional view illustrating an example of the area C shown in FIG. 7. This is that auxiliary lines are connected to each of a plurality of data lines adjacent to each other in the light emitting display apparatus shown in FIGS. 1 to 5. Therefore, in the following description, only the auxiliary line and the related configuration will be described, and the same reference numerals as in FIGS. 1 to 5 will be assigned to the remaining configurations, and redundant descriptions thereof will be simply described or omitted. Thus, repetitive descriptions of the same or similar elements may be omitted for brevity, and the descriptions provided for elements in one or more figures may also apply to elements in other figures that use the same or similar reference numerals unless stated otherwise.

Referring to FIGS. 6 to 8, the light emitting display apparatus according to another embodiment of the present disclosure may include an auxiliary line SL. The auxiliary line SL may overlap the pixel driving line PDL. Two adjacent data lines among the plurality of data lines DL may be formed between two adjacent sub-pixels among the plurality of sub-pixels 12a, 12b, and 12c. The auxiliary line SL may overlap the two adjacent data lines DL. The auxiliary line SL may overlap each of the first to sixth data lines DL1 to DL6. The auxiliary line SL may overlap each of the adjacent pixel power line PL and the reference power line RL. An auxiliary line SL may be disposed on the pixel power line PL and the reference power line RL, respectively.

According to an embodiment of the present disclosure, the buffer layer 110 may cover the pixel driving line PDL. The buffer layer 110 may be disposed between a pixel driving line PDL and an auxiliary line SL. The buffer layer 110 may be disposed on an upper portion of the pixel driving line PDL, which overlaps the auxiliary line SL. The buffer layer 110 may be disposed on an upper portion of the pixel driving line PDL overlapping the auxiliary line SL among the pixel driving lines PDL. The buffer layer 110 may be disposed on an upper portion of the first data line DL1, the second data line DL2, the first pixel power line PL1, and the first reference power line RL1. The buffer layer 110 may be disposed between the first data line DL1 and the second data line DL2 adjacent to each other. The buffer layer 110 may cover one side of the first data line DL1 and the second data line DL2 adjacent to each other. The buffer layer 110 may not be formed on the other side of each of the first data line DL1 and the second data line DL2 adjacent to the color filter layer CFL. Accordingly, the spaced area SA in which the buffer layer 110 is not formed may be disposed on the substrate 100. The spaced area SA may be covered by a color filter layer CFL to be described later.

The auxiliary line SL may be disposed on the substrate 100 along the first direction X. The auxiliary line SL may be disposed on the pixel driving line PDL. The auxiliary line SL may overlap the pixel driving line PDL. The auxiliary line SL may overlap a plurality of data lines DL, the pixel power line PL, and the reference power line RL.

The passivation layer 120 may be disposed on the buffer layer 110. The passivation layer 120 may be disposed between the first data line DL1 and the second data line DL2 adjacent to each other. The passivation layer 120 may cover side surfaces of the insulating layer 130 adjacent to each other. The passivation layer 120 may cover side surfaces and a portion of the upper surface of the auxiliary line SL adjacent to each other among the auxiliary lines SL. The passivation layer 120 may not be disposed in the spaced area SA formed on the upper surface of the substrate 100.

According to another embodiment of the present disclosure, ends of each of the red color filter CFr, the green color filter CFg, and the blue color filter CFb may cover a side surface of the pixel driving line PDL and a side surface of the auxiliary line SL adjacent to each other with the corresponding light emitting units EPr, EPg, and EPb interposed therebetween.

For example, one end of the red color filter CFr may cover a side surface of the first pixel power line PL1 and a side surface of the auxiliary line SL disposed on the first pixel power line PL1. The other end of the red color filter CFr may cover a side surface of the first data line DL1 and a side surface of the auxiliary line SL disposed on the first data line DL1.

For example, one end of the green color filter CFg may cover a side surface of the second data line DL2 and a side surface of the auxiliary line SL disposed on the second data line DL2. The other end of the green color filter CFg may cover a side surface of the first reference power line RL1 and a side surface of the auxiliary line SL disposed on the first reference power line RL1.

For example, one end of the blue color filter CFb may cover a side surface of the first reference power line RL1 and a side surface of the auxiliary line SL disposed on the first reference power line RL1. The other end of the blue color filter CFb may cover a side surface of the third data line DL3 of the adjacent pixel and a side surface of the auxiliary line SL disposed on the third data line DL3.

Each of the red color filter CFr, the green color filter CFg, and the blue color filter CFb may cover the spaced area SA between the passivation layer 120 and the pixel driving line PDL, which are spaced apart from each other. Accordingly, each of the red color filter CFr, the green color filter CFg, and the blue color filter CFb may be in partial contact with the upper surface of the substrate 100. Accordingly, the color filters CFr, CFg, and CFb disposed in each of the pixel areas SPA1 to SPA3 may be spaced apart from each other with the pixel driving line PDL and the auxiliary line SL interposed therebetween.

According to an embodiment of the present disclosure, the auxiliary line SL and the pixel driving line PDL may protrude in the direction of the color filter layer CFL rather than the buffer layer 110 and the insulating layer 130 disposed between the auxiliary line SL and the pixel driving line PDL.

The ends of the first data line DL1 and the auxiliary line SL disposed on the first data line DL1 adjacent to the red color filter CFr may protrude in the direction of the red color filter CFr. The ends of the auxiliary line SL disposed on the second data line DL2 and the second data line DL2 adjacent to the green color filter CFg may protrude in the direction of the green color filter CFg.

According to another embodiment of the present disclosure, the groove 145 may include first to fourth inclined parts 145aa to 145dd and first to third connection parts 145ee to 145gg.

In the first pixel area SPA1 and the second pixel area SPA2, the first inclined part 145a may overlap the red color filter CFr. The first inclined part 145aa may correspond to the inclined surface CFr-A of the red color filter CFr. The second inclined part 145bb may overlap the green color filter CFg. The second inclined part 145bb may correspond to the inclined surface CFg-A of the green color filter CFg. The third and fourth inclined parts 145cc and 145dd may correspond to inclined surfaces of the passivation layer 120 disposed between the first and second data lines DL1 and DL2 adjacent to each other. The first connection part 145ee may connect the first and third inclined parts 145aa and 145cc, the second connection part 145ff may connect the third and fourth inclined parts 145cc and 145dd, and the third connection part 145gg may connect the fourth and second inclined parts 145dd and 145bb. In some examples, a part may refer to a portion and vice versa.

According to another embodiment of the present disclosure, the groove 145 may be configured along the shapes of the color filter layer CFL and the auxiliary line SL without using a separate mask process (or a halftone mask process).

The cathode electrode CE may overlap the groove 145. The cathode electrode CE may be formed according to a shape of the groove 145. Accordingly, the cathode electrode CE overlapping the groove 145 may include four inclined portions and three connection portions.

Another embodiment of the present disclosure may have the same effect as that of the light emitting display apparatus according to an embodiment of the present disclosure.

According to another embodiment of the present disclosure, an auxiliary line SL may be formed in each of a plurality of data lines DL, and a buffer layer 110 and a passivation layer 120 may be disposed between a plurality of adjacent data lines DL. Accordingly, thereafter, in the process of forming the overcoat layer 140, a step coverage between a plurality of data lines DL may be reduced. In addition, the inclined surface of the groove 145 may be increased in the process of forming the overcoat layer 140, and the reflective surface of the cathode electrode CE corresponding to the inclined surface of the groove 145 may be increased in the process of forming the cathode electrode CE. Accordingly, light dissipated by the wave guide and light reflected from the inside of the substrate and dissipated may be emitted to the outside. Accordingly, light extraction efficiency may be maximized.

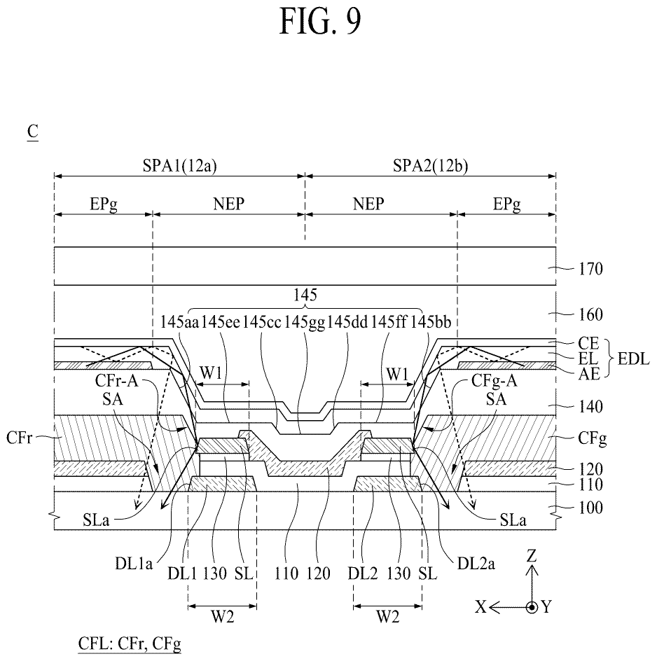

FIG. 9 is a cross-sectional view illustrating another example of the area C shown in FIG. 7. This is obtained by changing the width of the auxiliary line in the light emitting display apparatus illustrated in FIGS. 6 to 8. Accordingly, in the following description, only the auxiliary line and a related configuration will be described, the remaining configurations will be given the same reference numerals as in FIGS. 6 to 8, and redundant descriptions thereof will be simply described or omitted. Thus, repetitive descriptions of the same or similar elements may be omitted for brevity, and the descriptions provided for elements in one or more figures may also apply to elements in other figures that use the same or similar reference numerals unless stated otherwise.

Referring to FIG. 9, a light emitting display apparatus according to another embodiment of the present disclosure may include an auxiliary line SL. The auxiliary line SL may have a width different from that of the pixel driving line PDL. The width W1 of the auxiliary line SL may be less than the width W2 of the pixel driving line PDL. For example, the width W1 of each of the auxiliary lines SL on the plurality of data lines DL may be less than the width W2 of each of the plurality of data lines DL. Accordingly, side surfaces of the auxiliary line SL and the pixel driving line PDL according to another embodiment of the present disclosure may have a gentler slope than side surfaces of the auxiliary line SL and the pixel driving line PDL described with reference to FIGS. 6 to 8.

The color filter layer CFL may be formed along the side surfaces of the auxiliary line SL and the pixel driving line PDL. For example, ends of each of the red color filter CFr and the green color filter CFg may cover a side surface of the pixel driving line PDL and a side surface of the auxiliary line SL adjacent to each other with the corresponding light emitting portions EPr and EPg interposed therebetween.

According to another embodiment of the present disclosure, in the light emitting display apparatus, the width W1 of the auxiliary line SL is configured to be smaller than the width W2 of the pixel driving line PDL, and thus the slope of the color filter layer CFL covering the side surface of the pixel driving line PDL and the side surface of the auxiliary line SL may be smoothly configured. Accordingly, shapes of the groove 145 and the cathode electrode CE disposed later may be changed. For example, the angle of the inclined surface of the groove 145 may be smoothly configured, and the angle of the reflective surface of the cathode electrode CE may be smoothly configured.

According to another embodiment of the present disclosure, the width W1 of the auxiliary line SL is smaller than the width W2 of the pixel driving line PDL, and thus the angle of the inclined surface of the groove 145 and the reflective surface of the cathode electrode CE may be adjusted, and the light extraction efficiency of light emitted from the emission layer EL may be further increased.

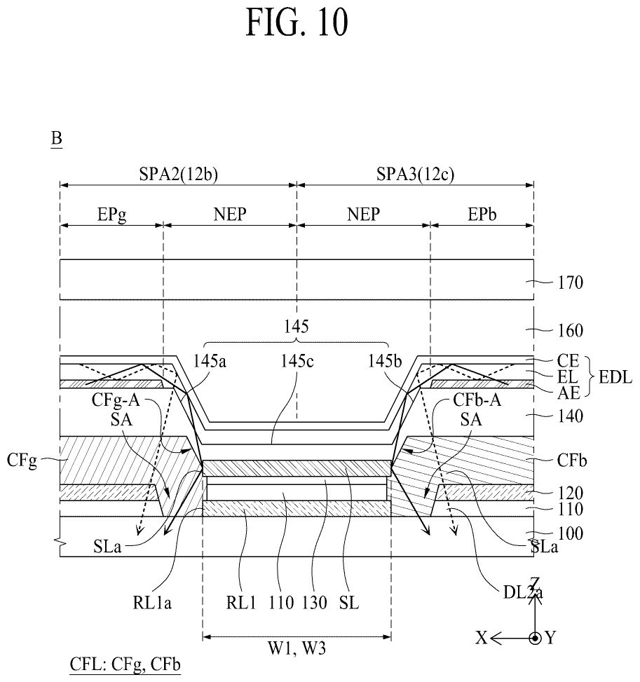

FIG. 10 is a cross-sectional view illustrating another example of the area B shown in FIG. 3. This is a change in the shapes of the pixel driving line and the auxiliary line in the light emitting display apparatus illustrated in FIGS. 2 to 5. Therefore, in the following description, only the shapes of the pixel driving line and the auxiliary line and a configuration related thereto are described, the same reference numerals as in FIGS. 6 to 8 are assigned to the remaining configurations, and redundant descriptions thereof are simply described or omitted. Thus, repetitive descriptions of the same or similar elements may be omitted for brevity, and the descriptions provided for elements in one or more figures may also apply to elements in other figures that use the same or similar reference numerals unless stated otherwise.

Referring to FIG. 10, according to another embodiment of the present disclosure, the auxiliary line SL may have the same shape as the pixel driving line PDL. For example, the auxiliary line SL and the pixel driving line PDL may have a vertical surface having an upper surface width equal to a width of a lower surface and a side surface perpendicular to the lower surface. For example, each cross section of the auxiliary line SL and the pixel driving line PDL may have a rectangular shape.

Accordingly, in the light emitting display apparatus according to another embodiment of the present disclosure, since the side surfaces of the auxiliary line SL and the pixel driving line PDL have a vertical surface, when the light emitted from the light emitting layer EL is reflected by the cathode electrode CE and proceeds in a lower direction, it may not proceed to the adjacent pixel area, but may be reflected back to any one of the auxiliary line SL and the pixel driving line PDL to emit light to the corresponding pixel area.

In the light emitting display apparatus according to another embodiment of the present disclosure, since the side surfaces of the auxiliary line SL and the pixel driving line PDL have a vertical surface, some light reflected by the cathode electrode CE may be reflected by the auxiliary line SL and emitted toward the substrate 100, and the remaining light of another path may be reflected on the side surface of the pixel driving line PDL and emitted toward the substrate 100, thereby further improving light extraction efficiency. For example, in the light emitting display apparatus according to another embodiment of the present disclosure, since the side surfaces of the auxiliary line SL and the pixel driving line PDL have a vertical surface, some light reflected by the cathode electrode CE may be reflected on both the side surface of the auxiliary line SL and the side surface of the pixel driving line PDL to emit light in the direction of the substrate 100, thereby further improving light extraction efficiency.

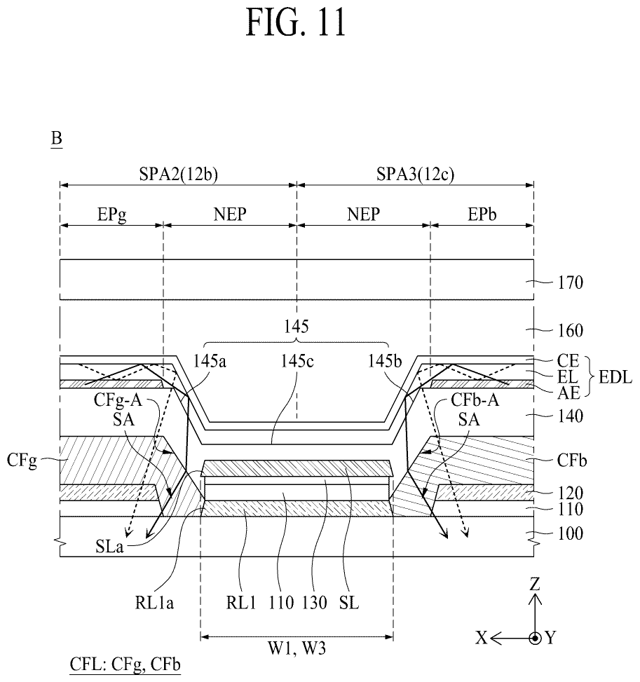

FIG. 11 is a cross-sectional view illustrating another example of the area B shown in FIG. 3. This is a change in the shape of the color filter layer in the light emitting display apparatus illustrated in FIGS. 2 to 5. Therefore, in the following description, only the shape of the color filter layer and a configuration related thereto will be described, the remaining configurations will be given the same reference numerals as in FIGS. 6 to 8, and redundant descriptions thereof will be simply described or omitted. Thus, repetitive descriptions of the same or similar elements may be omitted for brevity, and the descriptions provided for elements in one or more figures may also apply to elements in other figures that use the same or similar reference numerals unless stated otherwise.

Referring to FIG. 11, a light emitting display apparatus according to another embodiment of the present disclosure may include a color filter layer CFL. The color filter layer CFL may include a red color filter CFr, a green color filter CFg, and a blue color filter CFb. Hereinafter, a light emitting display apparatus according to another embodiment of the present disclosure will be described by using the green color filter CFg and the blue color filter CFb as examples for convenience of description. As another example, the configuration according to another embodiment of the present invention may also be applied to the red color filter CFr and the green color filter CFg.

According to another embodiment of the present disclosure, the color filter layer CFL is in contact with the pixel driving line PDL and may be spaced apart from the auxiliary line SL. An end of the color filter layer CFL may cover a side surface of the pixel driving line PDL adjacent to each other with the corresponding light emitting portions EPg and EPb interposed therebetween. An end of the color filter layer CFL may not be formed on a side surface of the auxiliary line SL. For example, the green color filter CFg of the second sub-pixel area SPA2 may contact the pixel driving line PDL and may be spaced apart from the auxiliary line SL. The green color filter CFg of the second sub-pixel area SPA2 may contact the first reference power line RL1 and may be spaced apart from the auxiliary line SL. For example, the blue color filter CFb of the third sub-pixel area SPA3 may contact the pixel driving line PDL and may be spaced apart from the auxiliary line SL. The blue color filter CFb of the third sub-pixel area SPA3 may contact the first reference power line RL1 and may be spaced apart from the auxiliary line SL.

According to another embodiment of the present disclosure, by adjusting the exposure amount in the process of forming the filter layer CFL, the end of the color filter layer CFL may be formed not to be in contact with the side surface of the auxiliary line SL. For example, the color filter layer CFL may be etched by increasing the exposure amount in the mask process. In this case, as the exposure amount increases, the end of the color filter layer CFL may be formed not to contact the side surface of the auxiliary line SL.

According to an embodiment of the present disclosure, since an end of the color filter layer CFL is not in contact with a side surface of the auxiliary line SL, the lengths of the inclined surfaces CFg-A and CFb-A of the color filter layer CFL may be increased. Accordingly, shapes of the groove 145 and the cathode electrode CE which are subsequently disposed may be disposed along the inclined surfaces CFg-A and CFb-A of the color filter layer CFL. For example, the inclined surface of the groove 145 may be elongated along the inclined surfaces CFg-A and CFb-A of the color filter layer CFL. For example, the inclined surface of the cathode electrode CE disposed later may be elongated.

According to another embodiment of the present disclosure, since the color filter layer CFL is spaced apart from the auxiliary line SL, the lengths of the inclined surfaces CFg-A and CFb-A of the color filter layer CFL and the inclined surfaces of the groove 145 may be increased. Accordingly, the light extraction efficiency of light emitted from the emission layer EL may be further improved.

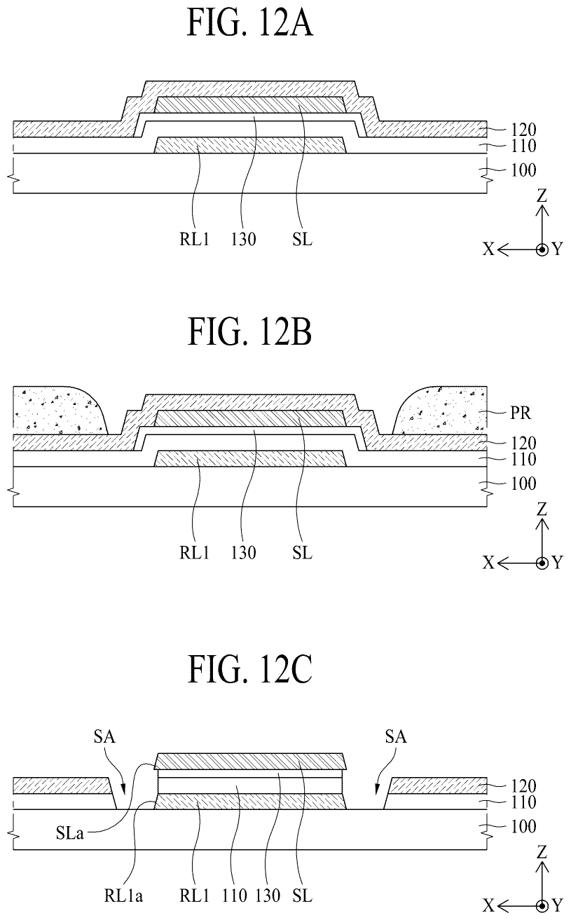

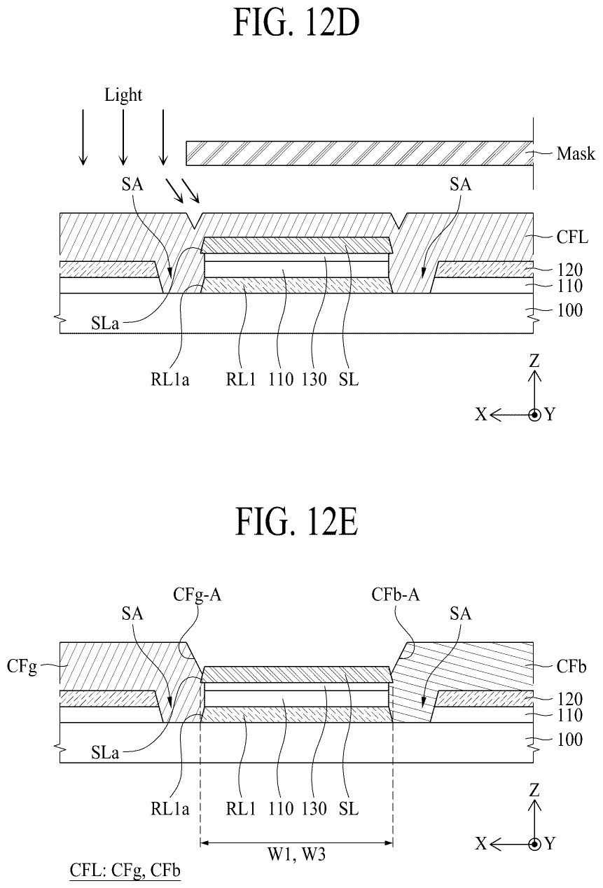

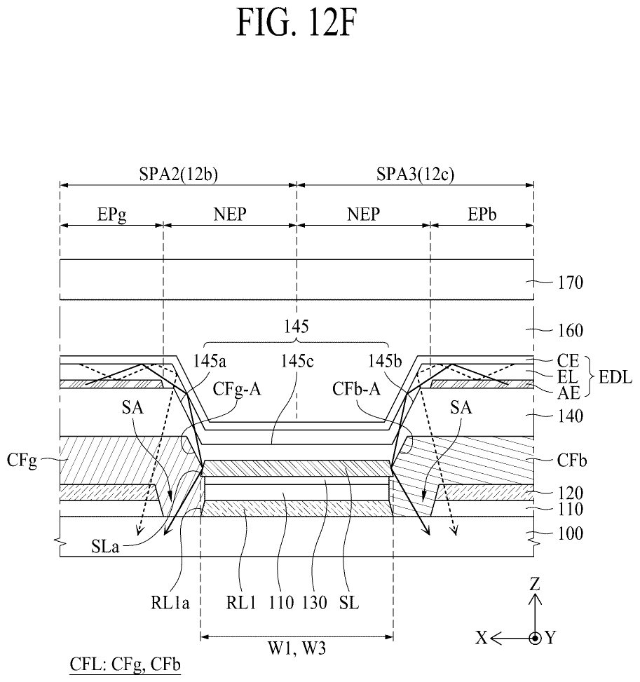

FIGS. 12A to 12F illustrate a method of manufacturing a light emitting display apparatus according to an embodiment of the present disclosure. This shows a method of manufacturing a light emitting display device described with reference to FIGS. 1 to 5. In FIGS. 12A to 12F, since the method of manufacturing areas A and B is the same, the method of manufacturing the present disclosure will be described by taking area B as an example for convenience of description. Further, in the following description, the same reference numerals as in FIGS. 1 to 5 are assigned, and redundant descriptions thereof are simply described or omitted. Thus, repetitive descriptions of the same or similar elements may be omitted for brevity, and the descriptions provided for elements in one or more figures may also apply to elements in other figures that use the same or similar reference numerals unless stated otherwise.

Referring to FIG. 12A, the pixel driving line PDL may be patterned on the substrate 100, and the buffer layer 110 may be formed on the entire surface of the substrate 100. The insulating layer 130 may be patterned on the buffer layer 110, and the auxiliary line SL may be patterned on the insulating layer 130. In this case, the auxiliary line SL and the pixel driving line PDL may be formed to have the same shape and the same width. Next, a passivation layer 120 may be formed on the entire surface of the substrate 100 to cover the pixel driving line PDL, the buffer layer 110, the insulating layer 130, and the auxiliary line SL.

Referring to FIG. 12B, a photoresist PR may be disposed in the remaining area of the passivation layer 120 except for the area overlapping the pixel driving line PDL and the auxiliary line SL and the spaced area SA.

Referring to FIG. 12C, the buffer layer 110, the insulating layer 130, and the passivation layer 120 may be patterned using exposure and etching processes. In this case, as the etchant penetrates into the lower portions of the pixel driving line PDL and the auxiliary line SL, an undercut-shaped side surface having widths of the pixel driving line PDL and the auxiliary line SL greater than widths of the buffer layer 110 and the insulating layer 130 may be formed.

Referring to FIG. 12D, a color filter material may be applied to the entire surface of the substrate, and a mask for exposure may be disposed to perform exposure and etching processes. The color filter material may be applied along a step coverage of the lower structure. During the exposure process, the end of the color filter may have an inclined surface in which the end of the color filter is inclined by diffraction of light occurring at the end of the mask. For example, the shape and length of the end of the color filter may be controlled by adjusting the exposure amount. For example, when the exposure amount is large, the etching amount of the end of the color filter increases, so that the end of the color filter layer CFL does not contact the side of the auxiliary line SL.

Referring to FIG. 12E, a color filter layer CFL may be formed in each sub-pixel area in the same manner as in FIG. 12D.

Referring to FIG. 12F, an overcoat layer 140, a light emitting device layer EDL, an encapsulation layer 160, and an encapsulation substrate 170 may be sequentially formed on a front surface thereof. In this case, a step may occur in the overcoat layer 140 by the color filter layer CFL and the auxiliary line SL. Further, a groove 145 may be formed in a portion overlapping the end of the color filter layer CFL and the auxiliary line SL. The light emitting layer EL and the cathode electrode CE of the light emitting device layer EDL are formed on a front surface of the substrate 100. Accordingly, the light emitting layer EL and the cathode electrode CE may be formed to have an inclined surface in the non-light emitting part NEP along the shape of the groove 145.

According to an embodiment of the present disclosure, the method of manufacturing a light emitting display apparatus includes an auxiliary line, thereby configuring a groove and a cathode electrode having an inclined surface between each sub-pixel without adding a separate mask process (e.g., a halftone mask process, etc.). Accordingly, light extraction efficiency of the light emitting display apparatus may be improved without increasing a manufacturing process and cost.

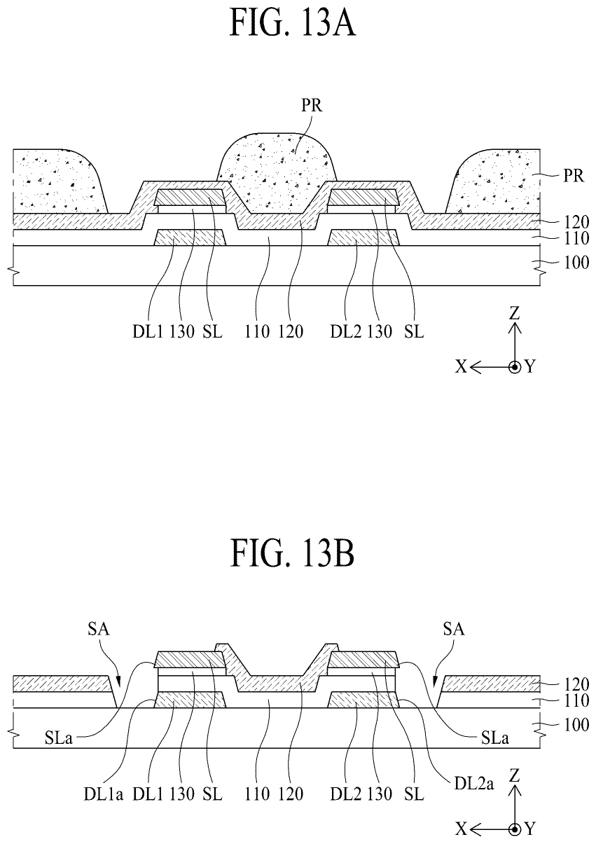

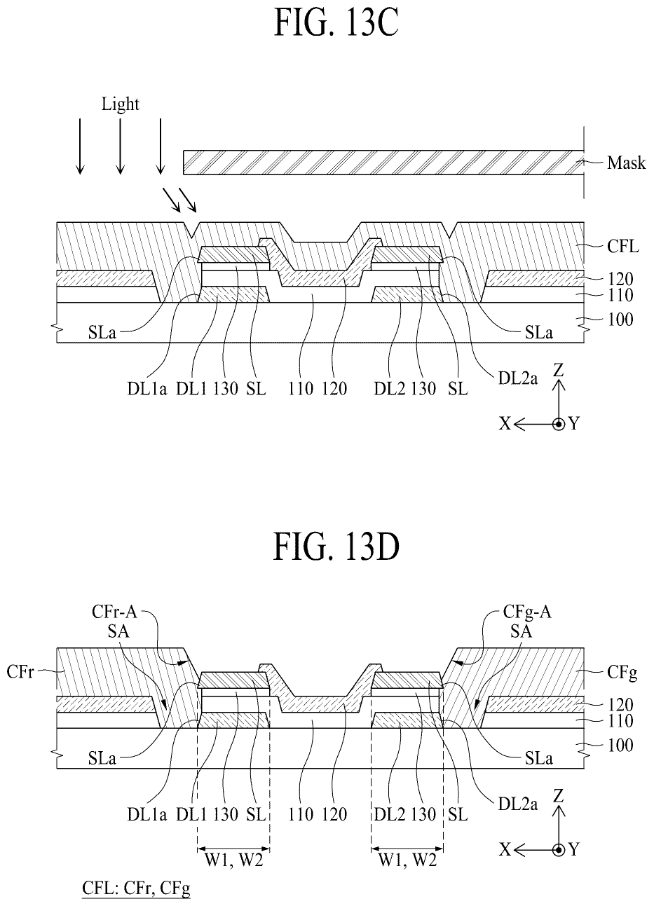

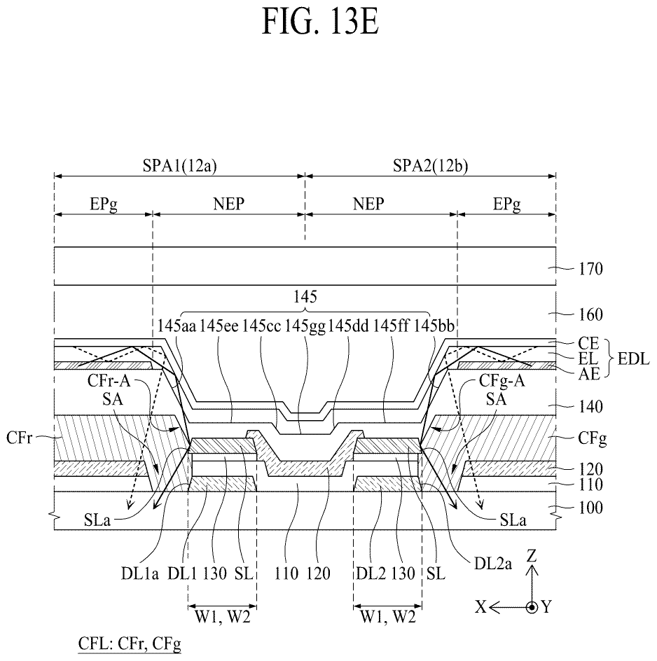

FIGS. 13A to 13E illustrate a method of manufacturing a light emitting display apparatus according to an embodiment of the present disclosure. This shows a method of manufacturing the light emitting display apparatus described with reference to FIGS. 6 to 8. In FIGS. 13A to 13E, the method of preparing area B is the same as that of FIGS. 12A to 12F, and thus a method of preparing the present disclosure will be described below by taking area A as an example. In addition, in the following description, the same reference numerals as in FIGS. 6 to 8 are assigned, and redundant descriptions thereof are simply explained or omitted. Thus, repetitive descriptions of the same or similar elements may be omitted for brevity, and the descriptions provided for elements in one or more figures may also apply to elements in other figures that use the same or similar reference numerals unless stated otherwise.

The process of forming the pixel driving line PDL, the buffer layer 110, the insulating layer 130, the auxiliary line SL, and the passivation layer 120 on the substrate 100 is the same as that of FIG. 12A.

Referring to FIG. 13A, a photoresist may be disposed in an area of the passivation layer 120 except for the area overlapping the pixel driving line PDL and the auxiliary line SL and the spaced area SA. In this case, a photoresist may be disposed between the adjacent auxiliary lines SL. The photoresist may be disposed to cover a portion of the upper surface of the adjacent auxiliary line SL.

Referring to FIG. 13B, the buffer layer 110, the insulating layer 130, and the passivation layer 120 may be patterned using exposure and etching processes. In this case, an etchant penetrates into lower portions of the pixel driving line PDL and the auxiliary line SL. Accordingly, an undercut-shaped side surface having widths of the pixel driving line PDL and the auxiliary line SL greater than widths of the buffer layer 110 and the insulating layer 130 may be formed.

Referring to FIG. 13C, a color filter material may be applied to the entire surface of the substrate, and a mask for exposure may be disposed to perform exposure and etching processes. The color filter material may be applied along a step difference of the lower structure. During the exposure process, the end of the color filter may have an inclined surface in which the end of the color filter is inclined by diffraction of light generated at the end of the mask.

Referring to FIG. 13D, a color filter layer CFL may be formed in each sub-pixel area in the same manner as in FIG. 12C.

Referring to FIG. 13E, an overcoat layer 140, a light emitting device layer EDL, an encapsulation layer 160, and an encapsulation substrate 170 may be sequentially formed on a front surface thereof. In this case, a step may occur in the overcoat layer 140 by the color filter layer CFL and the auxiliary line SL. Further, a groove 145 may be formed in a portion overlapping the end and the auxiliary line SL of the color filter layer CFL. The light emitting layer EL and the cathode electrode CE of the light emitting device layer EDL are formed on a front surface of the substrate 100. Accordingly, the light emitting layer EL and the cathode electrode CE may be formed to have an inclined surface in the non-light emitting part NEP along the shape of the groove 145.

According to an embodiment of the present disclosure, the method of manufacturing a light emitting display apparatus includes an auxiliary line, thereby configuring a groove and a cathode electrode having an inclined surface between each sub-pixel without adding a separate mask process (e.g., a halftone mask process, etc.). Accordingly, light extraction efficiency of the light emitting display apparatus may be improved without increasing a manufacturing process and cost.

Unless the context clearly indicates otherwise, an element may include one or more elements, or a plurality of elements. In an example, unless the context clearly indicates otherwise, a pixel driving line may include one or more pixel driving lines, or a plurality of pixel driving lines; an auxiliary line may include one or more auxiliary lines, or a plurality of auxiliary lines; a groove may include one or more grooves, or a plurality of grooves; a light emitting device layer may include one or more light emitting device layers, or a plurality of light emitting device layers; a substrate may include one or more substrates, or a plurality of substrates; a gate line may include one or more gate lines, or a plurality of gate lines; a pixel circuit may include one or more pixel circuits, or a plurality of pixel circuits; a light emitting portion may include one or more light emitting portions, or a plurality of light emitting portions; a non-light emitting portion may include one or more non-light emitting portions, or a plurality of non-light emitting portions.

Various examples and aspects of the present disclosure are described below. These are provided as examples, and do not limit the scope of the present disclosure.

According to some embodiments of the present disclosure, a light emitting display apparatus comprises a substrate, a plurality of pixels, a pixel driving line provided along a first direction on the substrate, a gate line disposed on the substrate along a second direction crossing the first direction, an auxiliary line overlapping the pixel driving line, a pixel circuit connected to the pixel driving line, an overcoat layer covering the pixel circuit, a groove overlapping the auxiliary line; and a light emitting device layer disposed on the overcoat layer and connected to the pixel circuit.

According to some embodiments of the present disclosure, each of the plurality of pixels includes a plurality of sub-pixels. Each of the plurality of sub-pixels includes a light emitting portion overlapping the light emitting device layer, a non-light emitting portion overlapping the pixel driving line, and a circuit area overlapping the pixel circuit.

According to some embodiments of the present disclosure, the pixel driving line includes a plurality of pixel power lines spaced apart from each other along the first direction on the substrate, a plurality of data lines disposed between the plurality of pixel power lines along the first direction, and a plurality of reference power lines disposed between the plurality of data lines along the first direction. The auxiliary line overlaps one or more of the plurality of pixel power lines, the plurality of data lines, and the plurality of reference power lines.

According to some embodiments of the present disclosure, two adjacent data lines among the plurality of data lines are disposed between two adjacent sub-pixels among the plurality of sub-pixels. The auxiliary line overlaps one or more of the two adjacent data lines.

According to some embodiments of the present disclosure, two adjacent data lines among the plurality of data lines are disposed between two adjacent sub-pixels among the plurality of sub-pixels. Each of the plurality of pixel power lines is configured in a respective one of the plurality of pixels. The auxiliary line includes a plurality of auxiliary lines. One or more of the plurality of auxiliary lines overlap corresponding one or more of the two adjacent data lines. Each of some of the plurality of auxiliary lines overlaps a corresponding one of the plurality of pixel power lines.

According to some embodiments of the present disclosure, two adjacent data lines among the plurality of data lines are disposed between two adjacent sub-pixels among the plurality of sub-pixels. Each of the plurality of reference power lines is configured in a respective one of the plurality of pixels. The auxiliary line includes a plurality of auxiliary lines. One or more of the plurality of auxiliary lines overlap corresponding one or more of the two adjacent data lines. Each of some of the plurality of auxiliary lines overlaps a corresponding one of the plurality of reference power lines.

According to some embodiments of the present disclosure, the auxiliary line is disposed on a same layer as the gate line, and includes a same material as the gate line.

According to some embodiments of the present disclosure, the pixel circuit includes a driving transistor electrically connected to the light emitting device layer. The driving transistor includes a source electrode and a drain electrode on a same layer as the plurality of data lines, and a gate electrode on a same layer as the gate line. The auxiliary line is disposed on a same layer as the gate electrode and includes a same material as the gate electrode.

According to some embodiments of the present disclosure, the auxiliary line has a same width as the pixel driving line.

According to some embodiments of the present disclosure, the auxiliary line has a width different from that of the pixel driving line.

According to some embodiments of the present disclosure, each of the auxiliary line and the pixel driving line has an inclined surface. A width of an upper surface of each of the auxiliary line and the pixel driving line is smaller than a width of a lower surface of a respective one of the auxiliary line and the pixel driving line. A side surface of each of the auxiliary line and the pixel driving line is inclined.

According to some embodiments of the present disclosure, each of the auxiliary line and the pixel driving line has a vertical surface. A width of an upper surface of each of the auxiliary line and the pixel driving line is same as a width of a lower surface of a respective one of the auxiliary line and the pixel driving line. The vertical surface has a vertical side surface.

According to some embodiments of the present disclosure, the groove is configured on the overcoat layer and has a concave shape from an upper surface to a lower surface of the overcoat layer.

According to some embodiments of the present disclosure, a light emitting display apparatus further comprises a buffer layer disposed at, in, or on each of the light emitting portion and the non-light emitting portion, and covering the pixel driving line on the substrate, an insulating layer between the pixel driving line and the auxiliary line, a passivation layer at, in, or on the buffer layer disposed on the light emitting portion, and color filters disposed between the passivation layer and the overcoat layer. Each of the color filters is disposed at a respective one of the plurality of sub-pixels.

According to some embodiments of the present disclosure, the pixel driving line and the auxiliary line protrude in directions of adjacent color filters.

According to some embodiments of the present disclosure, adjacent color filters among the color filters are spaced apart from each other with the auxiliary line interposed therebetween.

According to some embodiments of the present disclosure, each of the color filters covers a side surface of the pixel driving line adjacent the color filters and a side surface of the auxiliary line adjacent the color filters.

According to some embodiments of the present disclosure, each of the color filters covers a side surface of the pixel driving line adjacent the color filters and is spaced apart from the auxiliary line.

According to some embodiments of the present disclosure, the groove includes at least two or more inclined portions and a connection portion connecting the at least two or more inclined portions. One or more of the at least two or more inclined portions overlap corresponding one or more ends of adjacent color filters.

According to some embodiments of the present disclosure, the light emitting device layer includes an anode electrode on the overcoat layer, a light emitting layer on the anode electrode, and a cathode electrode on the light emitting layer. The anode electrode is spaced apart from the groove, and the light emitting layer and the cathode electrode are disposed along a shape of the groove.

According to some embodiments of the present disclosure, a light emitting display apparatus comprises a substrate, a pixel driving line disposed on the substrate, an auxiliary line disposed on the pixel driving line and electrically connected to the pixel driving line, a groove on the auxiliary line and overlapping the auxiliary line, and a light emitting device layer disposed adjacent to the groove.

According to some embodiments of the present disclosure, an anode electrode of the light emitting device layer does not overlap the groove, and a light emitting layer and a cathode electrode of the light emitting device layer overlap the groove.

According to some embodiments of the present disclosure, the light emitting display apparatus further includes a color filer disposed between the light emitting device layer and the substrate.

According to some embodiments of the present disclosure, a distance between an upper surface of the auxiliary line and the substrate is less than a distance between an upper surface of the color filer and the substrate.

According to some embodiments of the present disclosure, the light emitting display apparatus further includes a passivation layer disposed between the color filter and the substrate.

According to some embodiments of the present disclosure, the passivation layer overlaps the color filter and the light emitting device layer, and the passivation layer does not overlap the groove and the auxiliary line.

The light emitting display apparatus according to the present disclosure may be applied to all electronic devices including the display device. For example, the light emitting display apparatus according to the present disclosure may be applied to or included in mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theatre apparatuses, theatre display apparatuses, TVs, wall paper display apparatuses, signage apparatuses, game machines, notebook computers, monitors, cameras, camcorders, and home appliances, or the like.

The description herein has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The description herein and the accompanying drawings provide non-limiting examples of the technical features of the present disclosure for illustrative purposes. In other words, the disclosed embodiments illustrate the scope of the technical features of the present disclosure and are not intended to be limiting in any respect. Thus, the scope of the present disclosure is not limited to the embodiments shown, but is to be accorded the widest scope consistent with the claims and their equivalents.

What is claimed is:

1. A light emitting display apparatus, comprising:
a substrate;
a plurality of pixels;
a pixel driving line provided along a first direction on the substrate;
a gate line disposed on the substrate along a second direction crossing the first direction;
an auxiliary line overlapping the pixel driving line;
a pixel circuit connected to the pixel driving line;
an overcoat layer covering the pixel circuit;
a groove overlapping the auxiliary line; and
a light emitting device layer disposed on the overcoat layer and connected to the pixel circuit.

2. The light emitting display apparatus of claim 1, wherein each of the plurality of pixels includes a plurality of sub-pixels, and
wherein each of the plurality of sub-pixels includes:
a light emitting portion overlapping the light emitting device layer;
a non-light emitting portion overlapping the pixel driving line; and
a circuit area overlapping the pixel circuit.

3. The light emitting display apparatus of claim 1, wherein the pixel driving line includes:
a plurality of pixel power lines spaced apart from each other along the first direction on the substrate;
a plurality of data lines disposed between the plurality of pixel power lines along the first direction; and
a plurality of reference power lines disposed between the plurality of data lines along the first direction, and
wherein the auxiliary line overlaps one or more of the plurality of pixel power lines, the plurality of data lines, and the plurality of reference power lines.

4. The light emitting display apparatus of claim 3, wherein each of the plurality of pixels includes a plurality of sub-pixels,
wherein two adjacent data lines among the plurality of data lines are disposed between two adjacent sub-pixels among the plurality of sub-pixels, and
wherein the auxiliary line overlaps one or more of the two adjacent data lines.

5. The light emitting display apparatus of claim 3, wherein each of the plurality of pixels includes a plurality of sub-pixels,
wherein two adjacent data lines among the plurality of data lines are disposed between two adjacent sub-pixels among the plurality of sub-pixels,
wherein each of the plurality of pixel power lines is configured in a respective one of the plurality of pixels,
wherein the auxiliary line includes a plurality of auxiliary lines,
wherein one or more of the plurality of auxiliary lines overlap corresponding one or more of the two adjacent data lines, and
wherein each of some of the plurality of auxiliary lines overlaps a corresponding one of the plurality of pixel power lines.

6. The light emitting display apparatus of claim 3, wherein each of the plurality of pixels includes a plurality of sub-pixels,
wherein two adjacent data lines among the plurality of data lines are disposed between two adjacent sub-pixels among the plurality of sub-pixels,
wherein each of the plurality of reference power lines is configured in a respective one of the plurality of pixels,
wherein the auxiliary line includes a plurality of auxiliary lines,
wherein one or more of the plurality of auxiliary lines overlap corresponding one or more of the two adjacent data lines, and
wherein each of some of the plurality of auxiliary lines overlaps a corresponding one of the plurality of reference power lines.

7. The light emitting display apparatus of claim 1, wherein the auxiliary line is disposed on a same layer as the gate line, and includes a same material as the gate line.

8. The light emitting display apparatus of claim 3, wherein the pixel circuit includes a driving transistor electrically connected to the light emitting device layer,
wherein the driving transistor includes:
a source electrode and a drain electrode on a same layer as the plurality of data lines; and
a gate electrode on a same layer as the gate line, and
wherein the auxiliary line is disposed on a same layer as the gate electrode and includes a same material as the gate electrode.

9. The light emitting display apparatus of claim 1, wherein the auxiliary line has a same width as the pixel driving line.

10. The light emitting display apparatus of claim 1, wherein the auxiliary line has a width different from a width of the pixel driving line.

11. The light emitting display apparatus of claim 1, wherein each of the auxiliary line and the pixel driving line has an inclined surface,
wherein a width of an upper surface of each of the auxiliary line and the pixel driving line is smaller than a width of a lower surface of a respective one of the auxiliary line and the pixel driving line, and
wherein a side surface of each of the auxiliary line and the pixel driving line is inclined.

12. The light emitting display apparatus of claim 1, wherein each of the auxiliary line and the pixel driving line has a vertical surface,
wherein a width of an upper surface of each of the auxiliary line and the pixel driving line is same as a width of a lower surface of a respective one of the auxiliary line and the pixel driving line, and
wherein the vertical surface has a vertical side surface.

13. The light emitting display apparatus of claim 1, wherein the groove is configured on the overcoat layer and has a concave shape from an upper surface to a lower surface of the overcoat layer.

14. The light emitting display apparatus of claim 2, further comprising:
a buffer layer disposed at each of the light emitting portion and the non-light emitting portion, and covering the pixel driving line on the substrate;
an insulating layer between the pixel driving line and the auxiliary line;
a passivation layer on the buffer layer disposed at the light emitting portion; and
color filters disposed between the passivation layer and the overcoat layer,
wherein each of the color filters is disposed at a respective one of the plurality of sub-pixels.

15. The light emitting display apparatus of claim 14, wherein the pixel driving line and the auxiliary line protrude in directions of adjacent color filters.

16. The light emitting display apparatus of claim 14, wherein adjacent color filters among the color filters are spaced apart from each other with the auxiliary line interposed therebetween.

17. The light emitting display apparatus of claim 14, wherein each of the color filters covers a side surface of the pixel driving line adjacent the color filters and a side surface of the auxiliary line adjacent the color filters.

18. The light emitting display apparatus of claim 14, wherein each of the color filters covers a side surface of the pixel driving line adjacent the color filters and is spaced apart from the auxiliary line.

19. The light emitting display apparatus of claim 14, wherein the groove includes:
at least two or more inclined portions; and
a connection portion connecting the at least two or more inclined portions, and
wherein one or more of the at least two or more inclined portions overlap corresponding one or more ends of adjacent color filters.

20. The light emitting display apparatus of claim 1, wherein the light emitting device layer includes:
an anode electrode on the overcoat layer;
a light emitting layer on the anode electrode; and
a cathode electrode on the light emitting layer,
wherein the anode electrode is spaced apart from the groove, and
wherein the light emitting layer and the cathode electrode are disposed along a shape of the groove.
